(19) United States
(12) Patent Application Publication
(10) Pub. No.: US 2026/0107637 A1
(43) Pub. Date: Apr. 16, 2026

(54) ORGANIC LIGHT-EMITTING DISPLAY DEVICE

(71) Applicant: SeeYA Optronics Co., Ltd., Shanghai (CN)

(72) Inventors: Zhiyang Gao, Shanghai (CN); Chang-Ho Tseng, Shanghai (CN); Haifeng Cui, Shanghai (CN); Chao Wang, Shanghai (CN); Zhensong Zhang, Shanghai (CN); Yuchen Du, Shanghai (CN); Jie Wang, Shanghai (CN)

(73) Assignee: SeeYA Optronics Co., Ltd., Shanghai (CN)

(21) Appl. No.: 19/222,302

(22) Filed: May 29, 2025

(30) Foreign Application Priority Data
Oct. 14, 2024 (CN) 202411434045.X

(51) Int. Cl. H10K 59/122; H10K 59/80; H10K 102/00

(52) U.S. Cl. CPC H10K 59/122; H10K 59/80518; H10K 2102/351

(57) ABSTRACT

Provided are an organic light-emitting display device and a manufacturing method thereof. The organic light-emitting display device includes a substrate, anodes disposed in pixel regions, a first insulating layer filled between pixel regions, a second insulating layer disposed on the first insulating layer, a third insulating layer disposed on the second insulating layer, a fourth insulating layer disposed on the third insulating layer, and a fifth insulating layer disposed on the fourth insulating layer. The material of the second insulating layer is different from the material of the third insulating layer.

### CROSS-REFERENCE TO RELATED APPLICATION(S)

This application claims priority to Chinese Patent Application No. 202411434045.X, filed on Oct. 14, 2024, the disclosure of which is incorporated herein by reference in its entirety.

### TECHNICAL FIELD

The present disclosure relates to the field of display technologies and, in particular, to an organic light-emitting display device and a manufacturing method thereof.

### BACKGROUND

An organic light-emitting display device is a display device that uses an organic light-emitting diode (OLED) as a display pixel. Compared with traditional liquid crystal display devices, organic light-emitting display devices are increasingly popular in the market due to their advantages such as self-luminescence, low power consumption, excellent color effects, and suitability for flexible displays.

FIG. 1 is a sectional view showing a partial structure of an organic light-emitting display device in the related art. As shown in FIG. 1, pixels 20′ are arranged in an array on a side of the substrate 10′. Each of the pixels 20′ includes an anode 11′, an organic light-emitting layer 18′, and a cathode 19′ that are stacked. When an electron and a hole are injected into the organic light-emitting layer 18′ from the cathode 19′ and the anode 11′, respectively, the electron and the hole are recombined in the organic light-emitting layer 18′, releasing energy to emit light. The color of light emitted from a pixel′ 20′ may depend on the material of the organic light-emitting layer 18′.

A pixel defining layer 21′ is disposed on the anode 11′ and located between adjacent pixels 20′ to divide and define pixel regions.

The organic light-emitting layer 18′ is formed on the pixel defining layer 21′ and includes a first carrier adjustment layer 181′, a light-emitting material layer 182′, and a second carrier adjustment layer 183′ that are stacked in sequence. The first carrier adjustment layer 181′ and the second carrier adjustment layer 183′ are provided as entire layers. That is, the first carrier adjustment layer 181′ and the second carrier adjustment layer 183′ are continuous films across the pixels 20′.

A leakage current is generated on the first carrier adjustment layer 181′. This leakage current flows to the cathode 19′ through the light-emitting material layer 182′ above the pixel defining layer 21′, causing light leakage at corners and edges of the pixel 20′. This leakage current also weakens the current required by the pixel 20′ to emit light normally. As a result, the overall brightness of the pixel 20′ is reduced.

### SUMMARY

The present disclosure provides an organic light-emitting display device and a manufacturing method thereof to solve problems such as light leakage at corners and edges of a pixel and a non-uniform display within the pixel.

According to an aspect of the present disclosure, an organic light-emitting display device is provided. The organic light-emitting display device includes a substrate, anodes, a first insulating layer, a second insulating layer, a third insulating layer, a fourth insulating layer, and a fifth insulating layer.

The substrate includes multiple pixel regions disposed at intervals.

The anodes are disposed in the multiple pixel regions.

The first insulating layer is filled between pixel regions.

The second insulating layer is disposed on the first insulating layer.

The third insulating layer is disposed on the second insulating layer, where the material of the second insulating layer is different from the material of the third insulating layer.

The fourth insulating layer is disposed on the third insulating layer.

The fifth insulating layer is disposed on the fourth insulating layer, where the edge of the fifth insulating layer is beyond the edge of the fourth insulating layer.

According to another aspect of the present disclosure, a manufacturing method of an organic light-emitting display device is provided. The manufacturing method includes the steps described below.

A substrate is provided, where the substrate includes multiple pixel regions disposed at intervals.

Anodes are formed in the multiple pixel regions.

A first insulating material layer is formed on the anodes.

The first insulating material layer is etched so that first insulating layer is formed, where the first insulating layer is located between adjacent pixel regions.

A second insulating material layer is formed on the first insulating layer.

A third insulating material layer is formed on the second insulating material layer, where the material of the second insulating material layer is different from the material of the third insulating material layer.

A fourth insulating material layer is formed on the third insulating material layer.

A fifth insulating material layer is formed on the fourth insulating material layer.

The third insulating material layer, the fourth insulating material layer, and the fifth insulating material layer are etched so that a third insulating layer, a fourth insulating layer, and a fifth insulating layer are formed.

A sidewall of the fourth insulating layer is etched so that the edge of the fifth insulating layer is beyond the edge of the fourth insulating layer.

The second insulating material layer is etched so that second insulating layers are formed.

Embodiments of the present disclosure provide the organic light-emitting display device and the manufacturing method thereof. The third insulating layer, the fourth insulating layer, and the fifth insulating layer are stacked on the first insulating layer filled between the pixel regions. In addition, the edge of the fifth insulating layer is beyond the edge of the fourth insulating layer so that a first carrier adjustment layer in an organic light-emitting layer is cut off at the edge of the fifth insulating layer. Thus, the first carrier adjustment layer is prevented from forming a vertical leakage current between adjacent pixel regions, thereby reducing the light leakage at the corners and edges of the pixel. In addition, the supply of the current required by the pixel to emit light normally can be ensured, thereby improving the accuracy with which pixel brightness is controlled. Furthermore, the second insulating layer is disposed between the first insulating layer and the third insulating layer, and the material of the second insulating layer is different from the material of the third insulating layer. In an etching process to form the third, fourth, and fifth insulating layers, the second insulating layer is used for blocking etching so that the first insulating layer is protected from being damaged by etching. Thus, the quality and flatness of a subsequent film (such as the organic light-emitting layer) deposited on the first insulating layer are improved, thereby improving luminescence efficiency and uniformity.

It is to be understood that the content described in this section is neither intended to identify key or critical features of the embodiments of the present disclosure nor intended to limit the scope of the present disclosure. Other features of the present disclosure become easily understood through the description provided below.

### BRIEF DESCRIPTION OF DRAWINGS

To illustrate the technical solutions in the embodiments of the present disclosure more clearly, the drawings used in the description of the embodiments are briefly described below. Apparently, the drawings described below illustrate part of the embodiments of the present disclosure, and those of ordinary skill in the art may obtain other drawings based on the drawings described below on the premise that no creative work is done.

FIG. 1 is a sectional view showing a partial structure of an organic light-emitting display device in the related art;

FIG. 2 is a structural diagram of an organic light-emitting display device according to an embodiment of the present disclosure;

FIG. 3 is a sectional view taken along A-A′ of FIG. 2;

FIG. 4 is a sectional view showing a partial structure of an organic light-emitting display device according to an embodiment of the present disclosure;

FIG. 5 is a schematic diagram showing a film structure of a pixel according to an embodiment of the present disclosure;

FIG. 6 is another schematic diagram showing a film structure of a pixel according to an embodiment of the present disclosure;

FIG. 7 provides schematic diagrams showing a flow of a manufacturing method of an organic light-emitting display device according to an embodiment of the present disclosure;

FIG. 8 provides schematic diagrams showing a flow of a manufacturing method of an organic light-emitting display device according to an embodiment of the present disclosure;

FIG. 9 is another sectional view showing a partial structure of an organic light-emitting display device according to an embodiment of the present disclosure;

FIG. 10 provides schematic diagrams showing a flow of a manufacturing method of an organic light-emitting display device according to an embodiment of the present disclosure;

FIG. 11 is another structural diagram of an organic light-emitting display device according to an embodiment of the present disclosure;

FIG. 12 is a sectional view taken along B-B′ of FIG. 11;

FIG. 13 is a structural diagram showing an evaporation process in the related art;

FIG. 14 is a structural diagram showing another evaporation process according to an embodiment of the present disclosure;

FIG. 15 is another sectional view showing a partial structure of an organic light-emitting display device according to an embodiment of the present disclosure;

FIG. 16 is another sectional view showing a partial structure of an organic light-emitting display device according to an embodiment of the present disclosure;

FIG. 17 is another sectional view showing a partial structure of an organic light-emitting display device according to an embodiment of the present disclosure;

FIG. 18 provides schematic diagrams showing a flow of a manufacturing method of an organic light-emitting display device according to an embodiment of the present disclosure;

FIG. 19 is another sectional view showing a partial structure of an organic light-emitting display device according to an embodiment of the present disclosure;

FIG. 20 is another sectional view showing a partial structure of an organic light-emitting display device according to an embodiment of the present disclosure;

FIG. 21 is another sectional view showing a partial structure of an organic light-emitting display device according to an embodiment of the present disclosure;

FIG. 22 is another flowchart of a manufacturing method of an organic light-emitting display device according to an embodiment of the present disclosure; and

FIGS. 23 to 33 are schematic diagrams showing a flow of a manufacturing method of an organic light-emitting display device according to an embodiment of the present disclosure.

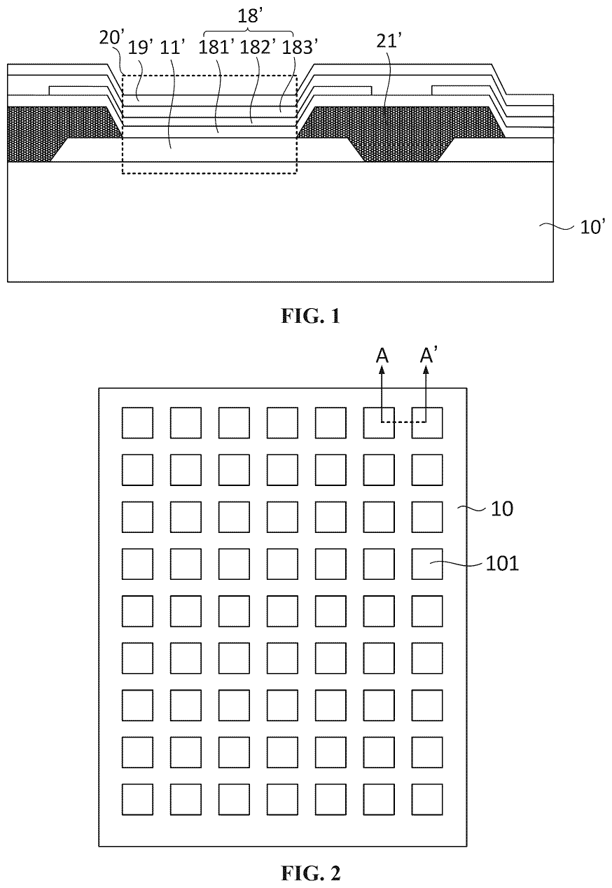

### DETAILED DESCRIPTION

To make the technical solutions of the present disclosure better understood by those skilled in the art, the technical solutions in the embodiments of the present disclosure are described below clearly and completely in conjunction with the drawings in the embodiments of the present disclosure. Apparently, the embodiments described below are part, not all, of the embodiments of the present disclosure. Based on the embodiments of the present disclosure, all other embodiments obtained by those of ordinary skill in the art are within the scope of the present disclosure on the premise that no creative work is done.

It is to be noted that terms such as “first” and “second” in the description, claims, and drawings of the present disclosure are used for distinguishing between similar objects and are not necessarily used for describing a particular order or sequence. It is to be understood that data used in this manner are interchangeable where appropriate so that the embodiments of the present disclosure described herein can be implemented in order not illustrated or described herein. In addition, the terms “including”, “having”, or any variations thereof are intended to encompass a non-exclusive inclusion. For example, a process, method, system, product, or device that includes a series of steps or units may include not only the expressly listed steps or units but also other steps or units that are not expressly listed or are inherent to such process, method, product, or device.

FIG. 2 is a structural diagram of an organic light-emitting display device according to an embodiment of the present disclosure, and FIG. 3 is a sectional view taken along A-A′ of FIG. 2. As shown in FIGS. 2 and 3, the organic light-emitting display device provided in the embodiment of the present disclosure includes a substrate 10, anodes 11, a first insulating layer 12, a second insulating layer 13, a third insulating layer 14, a fourth insulating layer 15, and a fifth insulating layer 16.

The substrate 10 includes multiple pixel regions 101 disposed at intervals.

The anodes 11 are disposed in the multiple pixel regions 101.

The first insulating layer 12 is filled between pixel regions 101.

The second insulating layer 13 is disposed on the first insulating layer 12.

The third insulating layer 14 is disposed on the second insulating layer 13, where the material of the second insulating layer 13 is different from the material of the third insulating layer 14.

The fourth insulating layer 15 is disposed on the third insulating layer 14.

The fifth insulating layer 16 is disposed on the fourth insulating layer 15, where the edge of the fifth insulating layer 16 is beyond the edge of the fourth insulating layer 15.

In one or more embodiments, as shown in FIGS. 2 and 3, the substrate 10 may be a driving substrate, and the multiple pixel regions 101 arranged in an array are defined on the substrate 10.

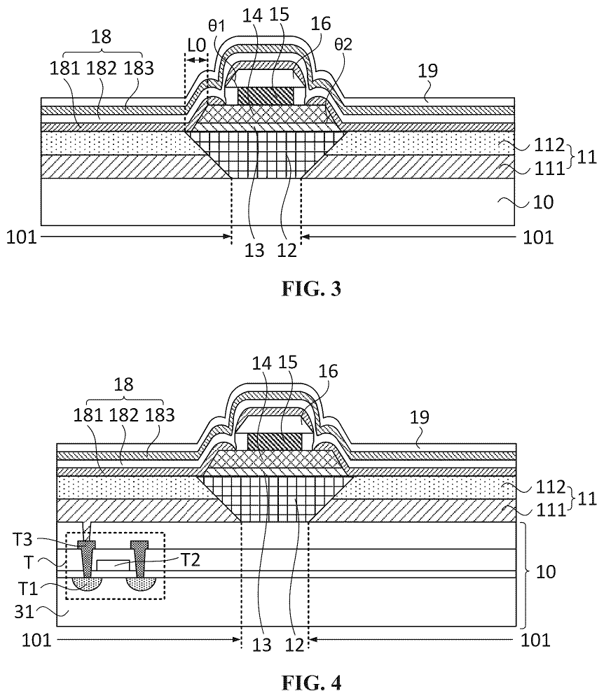

FIG. 4 is a sectional view showing a partial structure of an organic light-emitting display device according to an embodiment of the present disclosure. As shown in FIG. 4, in one or more embodiments, the substrate 10 includes a base 31. A drive transistor T corresponding to a pixel region 101 is disposed on the base 31. The drive transistor T is connected to the anode 11. The drive transistor T may supply, through the anode 11, an operating signal corresponding to brightness to a pixel, so as to drive the pixel to emit light.

The drive transistor T may include an active region T1, a gate T2, and a source and drain layer T3 that are stacked. The active region T1 may be formed in the base 31. The position of the active region T1 is not limited thereto and is not specifically limited in the embodiment of the present disclosure.

With continued reference to FIGS. 2 to 4, the anodes 11 are formed in the pixel regions 101 on the substrate 10. The anodes 11 corresponding to the pixel regions 101 are configured through electrical isolation. Each of the anodes 11, as an electrode of the pixel, may be driven by a positive voltage from an external power supply to inject carriers (such as holes) into the pixel.

Furthermore, as shown in FIGS. 3 and 4, the first insulating layer 12 is filled between adjacent anodes 11. In a lateral direction, the first insulating layer 12 is located between the two adjacent anodes 11. The first insulating layer 12 helps ensure electrical insulation between the two adjacent anodes 11. In addition, since each of the anodes 11 has a certain thickness, a depression is formed between the two anodes 11. The first insulating layer 12 is filled between the two adjacent anodes 11, which also helps reduce the height difference between each of the regions where the anodes 11 are located and the region where the depression is located. Thus, a subsequent film can be prepared on a relatively flat surface so that the continuity of the subsequent film can be ensured.

The material of the first insulating layer 12 may include at least one of silicon oxide (SiO) or silicon nitride (SiN). The silicon oxide and the silicon nitride have relatively high resistivity and can provide good insulation between the adjacent anodes 11. In addition, the silicon oxide and the silicon nitride also have very high chemical stability and excellent high-temperature stability and are less prone to corrosion from moisture, oxygen, and other harmful gases in the environment. The silicon oxide and the silicon nitride can maintain good insulating properties in a high-temperature environment, which helps prolong the service life of a device.

With continued reference to FIGS. 3 and 4, the third insulating layer 14, the fourth insulating layer 15, and the fifth insulating layer 16 are stacked on the first insulating layer 12. The third insulating layer 14, the fourth insulating layer 15, and the fifth insulating layer 16 are disposed around the pixel region 101 and define regions that may be in any shape such as a rectangle, a polygon, or a circle. The shapes of the regions are not specifically limited in the embodiment of the present disclosure.

Furthermore, the fifth insulating layer 16 covers the fourth insulating layer 15, and the edge of the fifth insulating layer 16 is beyond the edge of the fourth insulating layer 15. In this case, the distance between the vertical projection of the edge of the fifth insulating layer 16 on the substrate 10 and the vertical projection of the edge of the fourth insulating layer 15 on the substrate 10 is greater than 0. That is, the length of the fifth insulating layer 16 in the lateral direction is greater than the length of the fourth insulating layer 15 in the lateral direction. In other words, the projection area of the fifth insulating layer 16 on the substrate 10 is larger than the projection area of the fourth insulating layer 15 on the substrate 10. The opening formed in the fifth insulating layer 16 is smaller than the opening formed in the fourth insulating layer 15. Thus, the edge of the opening in the fifth insulating layer 16 protrudes more toward the inner side of the light-emitting region of the pixel than the edge of the opening in the fourth insulating layer 15, and the edge of the opening in the fourth insulating layer 15 is recessed away from the light-emitting region of the pixel relative to the edge of the opening in the fifth insulating layer 16. Accordingly, the edge portion of the fifth insulating layer 16 forms an eaves structure on the edge of the fourth insulating layer 15.

With continued reference to FIGS. 3 and 4, an organic light-emitting layer 18 disposed on the anode 11 is further included in the pixel region 101. The organic light-emitting layer 18 includes a first carrier adjustment layer 181, a light-emitting material layer 182, and a second carrier adjustment layer 183 that are stacked sequentially.

When the organic light-emitting layer 18 is prepared, the eaves structure at the edge of the fifth insulating layer 16 hides part of the upper surface of the third insulating layer 14, thereby forming a hidden region below the eaves structure at the edge of the fifth insulating layer 16. The first carrier adjustment layer 181 that is prone to generate a leakage current in the organic light-emitting layer 18 is partially deposited on the upper surface of the fifth insulating layer 16 and partially deposited on the upper surface of the third insulating layer 14. However, the first carrier adjustment layer 181 cannot be deposited in the hidden region. Thus, the first carrier adjustment layer 181 is cut off in the hidden region so that the first carrier adjustment layer 181 deposited on the upper surface of the fifth insulating layer 16 and the first carrier adjustment layer 181 deposited on the upper surface of the third insulating layer 14 cannot form a connection in the hidden region and are disconnected.

With such a configuration, the first carrier adjustment layer 181 can be prevented from forming a vertical leakage current between adjacent pixel regions 101, thereby reducing the light leakage at the corners and edges of the pixel. In addition, the supply of the current required by the pixel to emit light normally can be ensured, thereby helping improve the accuracy with which pixel brightness is controlled.

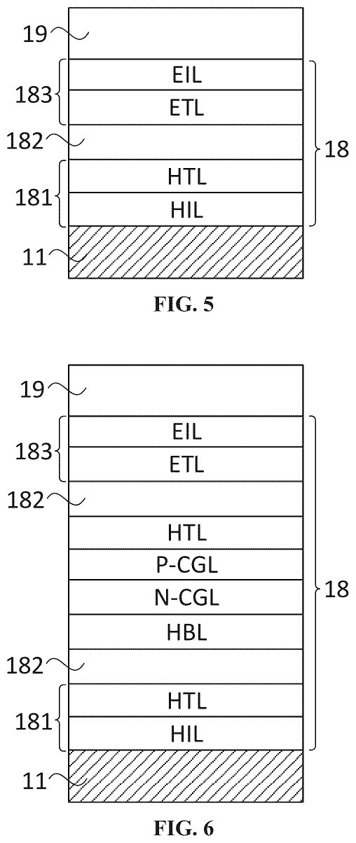

FIG. 5 is a schematic diagram showing a film structure of the pixel according to an embodiment of the present disclosure. As shown in FIG. 5, in one or more embodiments, the organic light-emitting layer 18 is located between the anode 11 and the cathode 19, the first carrier adjustment layer 181 is located between the anode 11 and the light-emitting material layer 182, and the second carrier adjustment layer 183 is located between the cathode 19 and the light-emitting material layer 182. The first carrier adjustment layer 181 may include a hole injection layer HIL and a hole transport layer HTL. The second carrier adjustment layer 183 may include an electron transport layer ETL and an electron injection layer EIL.

The hole injection layer HIL is located on the anode 11. The hole injection layer HIL is configured to reduce an energy barrier to the injection of a hole from the anode 11 into the organic light-emitting layer 18, enabling the hole to be more effectively transferred from the anode 11 to the hole transport layer HTL. Thus, hole injection efficiency is improved, thereby improving the luminescence efficiency and brightness of the pixel.

The hole transport layer HTL is located on the hole injection layer HIL. The hole transport layer HTL is configured to effectively transport the hole injected from the anode 11 to the light-emitting material layer 182 so as to ensure that the hole is effectively recombined with an electron in the light-emitting material layer 182 to generate a photon.

The electron transport layer ETL is located on the light-emitting material layer 182. The electron transport layer ETL is configured to effectively transport the electron from the cathode 19 to the light-emitting material layer 182 so as to ensure that the electron can be quickly and efficiently transported to the light-emitting material layer 182 and be recombined with the hole to emit the photon.

The electron injection layer EIL is located on the electron transport layer ETL. The electron injection layer EIL is configured to reduce an energy barrier to the injection of the electron from the cathode 19 into the light-emitting material layer 182. Thus, electron injection efficiency is improved. In addition, the electron injection layer EIL can ensure good interface contact and energy level matching with both the cathode 19 and the electron transport layer ETL, ensuring that the electron can be injected into the light-emitting material layer 182 easily to participate in a light emission process.

With continued reference to FIGS. 3 to 5, for example, the hole injection layer HIL and the hole transport layer HTL may be disconnected in the hidden region below the eaves structure at the edge of the fifth insulating layer 16. Thus, the hole injection layer HIL and the hole transport layer HTL are prevented from forming the vertical leakage current between the adjacent pixel regions 101, thereby reducing the light leakage at the corners and edges of the pixel. In addition, the supply of the current required by the pixel to emit light normally can be ensured, thereby helping improve the accuracy with which the pixel brightness is controlled.

FIG. 6 is another schematic diagram showing a film structure of the pixel according to an embodiment of the present disclosure. As shown in FIG. 6, in one or more embodiments, the pixel may adopt a tandem OLED structure. The tandem OLED connects two or even more light-emitting material layers in series through a charge generation layer CGL. The charge generation layer can reduce a drive voltage and generate a new carrier. The multiple light-emitting material layers in series can multiply the luminescence efficiency of the pixel. In addition, at the same brightness, the current density of the tandem OLED decreases, which can significantly prolong the service life of the device.

For example, as shown in FIG. 6, an n-type charge generation layer N-CGL and a p-type charge generation layer P-CGL collectively constitute the charge generation layer. The n-type charge generation layer may be made of an organic electron transport material doped with a metal material. The p-type charge generation layer may be made of an organic hole transport material doped with a p-type light-emitting dopant (that is, a p-dopant (PD)).

Furthermore, as shown in FIG. 6, description is performed by using an example in which the two light-emitting material layers are connected in series. The first carrier adjustment layer 181 may include the hole injection layer HIL and the hole transport layer HTL. The second carrier adjustment layer 183 may include the electron transport layer ETL and the electron injection layer EIL. A hole blocking layer HBL, the n-type charge generation layer N-CGL, the p-type charge generation layer P-CGL, and the hole transport layer HTL may be sequentially stacked between the two light-emitting material layers 182, but are not limited thereto.

The n-type charge generation layer N-CGL and the p-type charge generation layer P-CGL are each configured to be an entire layer. That is, the n-type charge generation layer N-CGL and the p-type charge generation layer P-CGL are continuous films across pixels. When the organic light-emitting display device operates, the leakage current is prone to flow laterally through the n-type charge generation layer N-CGL and the p-type charge generation layer P-CGL, thereby causing crosstalk.

With continued reference to FIGS. 3 and 6, in one or more embodiments, the n-type charge generation layer N-CGL, the p-type charge generation layer P-CGL, and the hole blocking layer HBL, the light-emitting material layer 182, and the first carrier adjustment layer 181 that are located under the n-type charge generation layer N-CGL may be disconnected in the hidden region below the eaves structure at the edge of the fifth insulating layer 16. The n-type charge generation layer N-CGL, the p-type charge generation layer P-CGL, and the films under the n-type charge generation layer N-CGL are prevented from forming the leakage current between the adjacent pixel regions 101, thereby reducing the crosstalk.

In other embodiments, the specific film structure in the first carrier adjustment layer 181, the specific film structure in the second carrier adjustment layer 183, and the specific film cut off by the eaves structure at the edge of the fifth insulating layer 16 may be each configured according to actual requirements and are not specifically limited in the embodiment of the present disclosure.

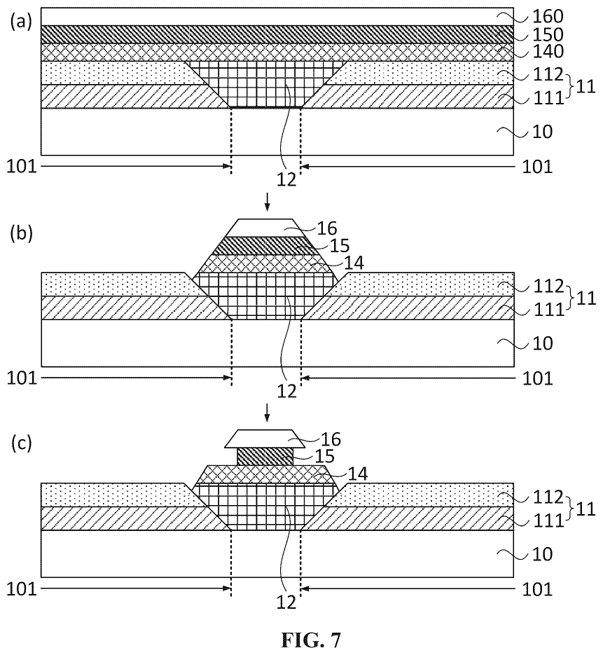

FIG. 7 provides schematic diagrams showing a flow of a manufacturing method of the organic light-emitting display device according to an embodiment of the present disclosure. As shown in FIG. 7, in the related art, when the organic light-emitting display device is prepared, an entire third insulating material layer 140, an entire fourth insulating material layer 150, and an entire fifth insulating material layer 160 are sequentially deposited on the first insulating layer 12 as shown in FIG. 7(a). As shown in FIG. 7(b), the third insulating material layer 140, the fourth insulating material layer 150, and the fifth insulating material layer 160 are etched so that the third insulating layer 14, the fourth insulating layer 15, and the fifth insulating layer 16 are formed. As shown in FIG. 7(c), the sidewall of the fourth insulating layer 15 is etched so that the edge of the fifth insulating layer 16 is beyond the edge of the fourth insulating layer 15.

The inventor found through research that the first insulating layer 12 under the third insulating layer 14 is damaged in the preceding etching process. As a result, the quality and flatness of the subsequent film (such as the organic light-emitting layer) deposited on the first insulating layer 12 are affected, and thus, the luminescence efficiency and uniformity are affected.

Based on the preceding technical problem, as shown in FIGS. 3 and 4, in this embodiment, the second insulating layer 13 is disposed between the first insulating layer 12 and the third insulating layer 14.

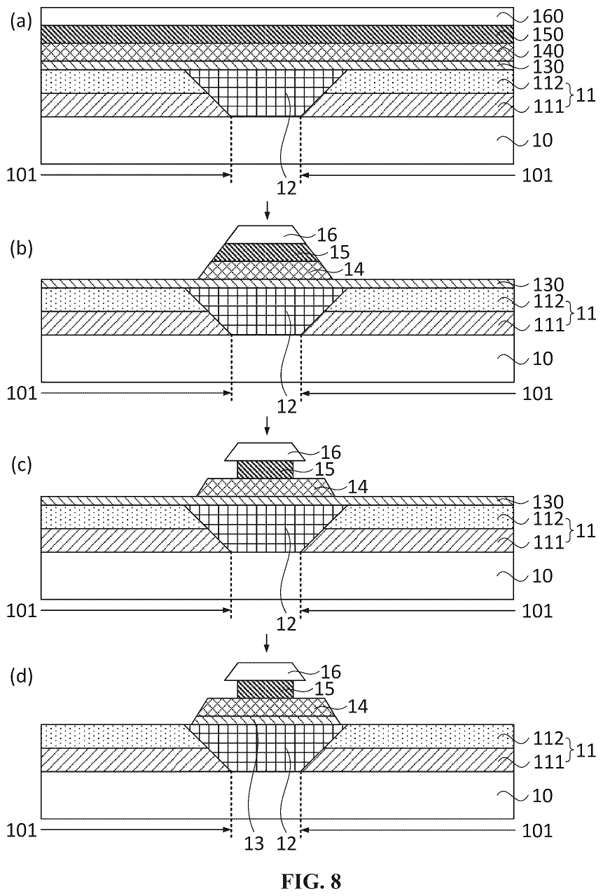

FIG. 8 provides schematic diagrams showing a flow of the manufacturing method of the organic light-emitting display device according to an embodiment of the present disclosure. As shown in FIG. 8, in this embodiment, when the organic light-emitting display device is prepared, an entire second insulating material layer 130, the entire third insulating material layer 140, the entire fourth insulating material layer 150, and the entire fifth insulating material layer 160 may be sequentially deposited on the first insulating layer 12 as shown in FIG. 8(a). As shown in FIG. 8(b), the third insulating material layer 140, the fourth insulating material layer 150, and the fifth insulating material layer 160 are etched so that the third insulating layer 14, the fourth insulating layer 15, and the fifth insulating layer 16 are formed. As shown in FIG. 8(c), the sidewall of the fourth insulating layer 15 is etched so that the edge of the fifth insulating layer 16 is beyond the edge of the fourth insulating layer 15. As shown in FIG. 8(d), the second insulating material layer 130 is etched so that the second insulating layer 13 is formed.

The material of the second insulating layer 13 is different from the material of the third insulating layer 14, that is, the material of the second insulating material layer 130 is different from the material of the third insulating material layer 140. Then, in the preceding process where the third insulating material layer 140, the fourth insulating material layer 150, and the fifth insulating material layer 160 are etched, since the material of the second insulating material layer 130 is different, the second insulating material layer 130 can protect the first insulating layer 12 under the second insulating material layer 130 so that the first insulating layer 12 is prevented from being damaged by etching. Thus, the quality and flatness of the subsequent film (such as the organic light-emitting layer) deposited on the first insulating layer 12 are improved, thereby improving the luminescence efficiency and the uniformity.

In one or more embodiments, the material of the fifth insulating layer 16 includes at least one of silicon nitride (SiN), silicon oxide (SiO), silicon oxynitride (SiON), or amorphous silicon (a-Si); and/or, the material of the fourth insulating layer 15 includes at least one of silicon nitride (SiN), silicon oxide (SiO), silicon oxynitride (SiON), or amorphous silicon (a-Si); and/or, the material of the third insulating layer 14 includes at least one of silicon nitride (SiN), silicon oxide (SiO), silicon oxynitride (SiON), or amorphous silicon (a-Si).

The silicon nitride (SiN), the silicon oxide (SiO), and the silicon oxynitride (SiON) have relatively high resistivity and can provide good insulation for the first carrier adjustment layer 181 located on the upper surface of the third insulating layer 14. In addition, the silicon nitride (SiN), the silicon oxide (SiO), and the silicon oxynitride (SiON) also have good chemical stability and thermal stability. The silicon nitride (SiN), the silicon oxide (SiO), and the silicon oxynitride (SiON) can maintain good insulating properties in a high-temperature environment, which helps prolong the service life of the device.

The amorphous silicon (a-Si) may be deposited with various deposition methods, such as plasma-enhanced chemical vapor deposition (PECVD). The amorphous silicon (a-Si) has good process compatibility and good mechanical stability and can provide strong structural support, which helps ensure the stability of the structure in subsequent processes.

In summary, the embodiments of the present disclosure provide the organic light-emitting display device. The third insulating layer, the fourth insulating layer, and the fifth insulating layer are stacked on the first insulating layer filled between the pixel regions. In addition, the edge of the fifth insulating layer is beyond the edge of the fourth insulating layer so that the first carrier adjustment layer in the organic light-emitting layer is cut off at the edge of the fifth insulating layer. Thus, the first carrier adjustment layer is prevented from forming the vertical leakage current between the adjacent pixel regions, thereby reducing the light leakage at the corners and edges of the pixel. In addition, the supply of the current required by the pixel to emit light normally can be ensured, thereby improving the accuracy with which the pixel brightness is controlled. Furthermore, the second insulating layer is disposed between the first insulating layer and the third insulating layer, and the material of the second insulating layer is different from the material of the third insulating layer. In the etching process to form the third, fourth, and fifth insulating layers, the second insulating layer is used for block etching so that the first insulating layer is protected from being damaged by etching. Thus, the quality and flatness of the subsequent film (such as the organic light-emitting layer) deposited on the first insulating layer are improved, thereby improving the luminescence efficiency and the uniformity.

With continued reference to FIG. 8, in one or more embodiments, the material of the second insulating layer 13 is different from the material of the first insulating layer 12.

In one or more embodiments, as shown in FIG. 8(d), after the third insulating layer 14, the fourth insulating layer 15, and the fifth insulating layer 16 are formed, the second insulating material layer 130 is etched so that the second insulating material layer 130 on the anode 11 is removed, forming the second insulating layer 13. The material of the second insulating layer 13 is different from the material of the first insulating layer 12, that is, the material of the second insulating material layer 130 is different from the material of the first insulating layer 12. Then, in the preceding process where the second insulating material layer 130 is etched, an etchant with high selectivity to the material of the second insulating material layer 130 may be selected, thereby reducing the damage to the first insulating layer 12 in the process where the second insulating material layer 130 is etched.

With continued reference to FIG. 8, in one or more embodiments, the thickness of the second insulating layer 13 is 5 nm to 50 nm.

The thickness of the second insulating layer 13 is greater than or equal to 5 nm. In this case, the second insulating material layer 130 for forming the second insulating layer 13 is sufficiently thick. In the process where the third insulating material layer 140, the fourth insulating material layer 150, and the fifth insulating material layer 160 are etched, it can be ensured that the second insulating material layer 130 is not completely removed in the etching process and thus can provide sufficient protection for the first insulating layer 12.

Furthermore, the thickness of the second insulating layer 13 is less than or equal to 50 nm. In this case, the second insulating material layer 130 for forming the second insulating layer 13 is not excessively thick. Then, in the process where the second insulating material layer 130 is etched to form the second insulating layer 13, no etching difficulty or no increase in process complexity is caused due to an excessively thick second insulating material layer 130.

In one or more embodiments, the material of the second insulating layer 13 includes at least one of aluminum oxide (Al₂O₃), titanium oxide (TiO₂), zirconium oxide (ZrO₂), or hafnium oxide (HfO₂).

The material of the second insulating layer 13 is different from the material of the third insulating layer 14 and the material of the first insulating layer 12. Then, the material of the second insulating material layer 130 for forming the second insulating layer 13 is different from the material of the third insulating layer 14 and the material of the first insulating layer 12 to achieve etching selectivity.

As shown in FIG. 8, in the process where the third insulating material layer 140, the fourth insulating material layer 150, and the fifth insulating material layer 160 are etched, an etchant with high selectivity to the materials of the third insulating material layer 140, the fourth insulating material layer 150, and the fifth insulating material layer 160 may be selected. Then, in the etching process, the second insulating material layer 130 can protect the first insulating layer 12 under the second insulating material layer 130 so that the damage to the first insulating layer 12 is reduced. Thus, the structural integrity of the first insulating layer 12 is protected.

In addition, the aluminum oxide (Al₂O₃), the titanium oxide (TiO₂), the zirconium oxide (ZrO₂), and the hafnium oxide (HfO₂) have good chemical stability and mechanical strength, which help resist corrosion from an external environment and prolong the service life of the device.

With continued reference to FIGS. 3 and 4, in one or more embodiments, the vertical projection of the second insulating layer 13 on the substrate 10 covers the vertical projection of the third insulating layer 14 on the substrate 10.

As shown in FIGS. 3 and 4, the edge of the second insulating layer 13 may be beyond the edge of the third insulating layer 14. That is, the length of the second insulating layer 13 in the lateral direction may be greater than the length of the third insulating layer 14 in the lateral direction. In other words, the projection area of the second insulating layer 13 on the substrate 10 is larger than the projection area of the third insulating layer 14 on the substrate 10.

With such a configuration, when the first carrier adjustment layer 181 is prepared, the first carrier adjustment layer 181 is sequentially raised at the edge of the second insulating layer 13 and the edge of the third insulating layer 14. Thus, the transmission path length of the current on the first carrier adjustment layer 181 can be increased, which helps reduce the leakage current between the adjacent pixel regions 101.

FIG. 9 is another sectional view showing a partial structure of the organic light-emitting display device according to an embodiment of the present disclosure. As shown in FIG. 9, in one or more embodiments, the vertical projection of the second insulating layer 13 on the substrate 10 coincides with the vertical projection of the third insulating layer 14 on the substrate 10.

The vertical projection of the second insulating layer 13 on the substrate 10 is configured to coincide with the vertical projection of the third insulating layer 14 on the substrate 10. Thus, when the second insulating layer 13 is prepared, the third insulating layer 14 can be directly used as a mask for etching.

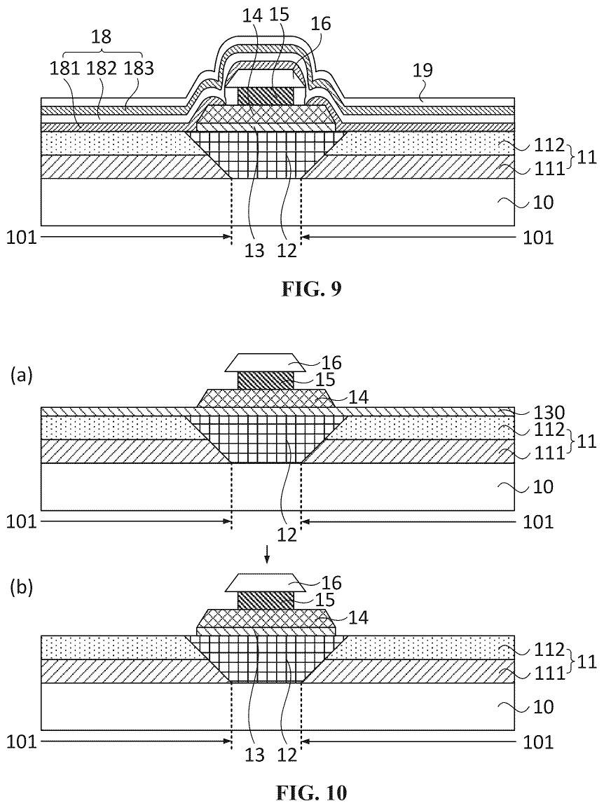

In one or more embodiments, FIG. 10 provides schematic diagrams showing a flow of the manufacturing method of the organic light-emitting display device according to an embodiment of the present disclosure. As shown in FIG. 10(a), the second insulating material layer 130 is etched to form the second insulating layer 13. Third insulating layers 14 can be directly used as the mask to etch the second insulating material layer 130, eliminating the need for an additional mask. Thus, manufacturing costs can be reduced, the process is simplified, and production efficiency is improved.

In addition, as shown in FIG. 10(b), the third insulating layer 14 is used as the mask so that higher etching precision can be achieved and it is ensured that the edge of the second insulating layer 13 is aligned with the edge of the third insulating layer 14. Thus, problems such as interlayer misalignment caused by a process error introduced by an additional masking step are reduced.

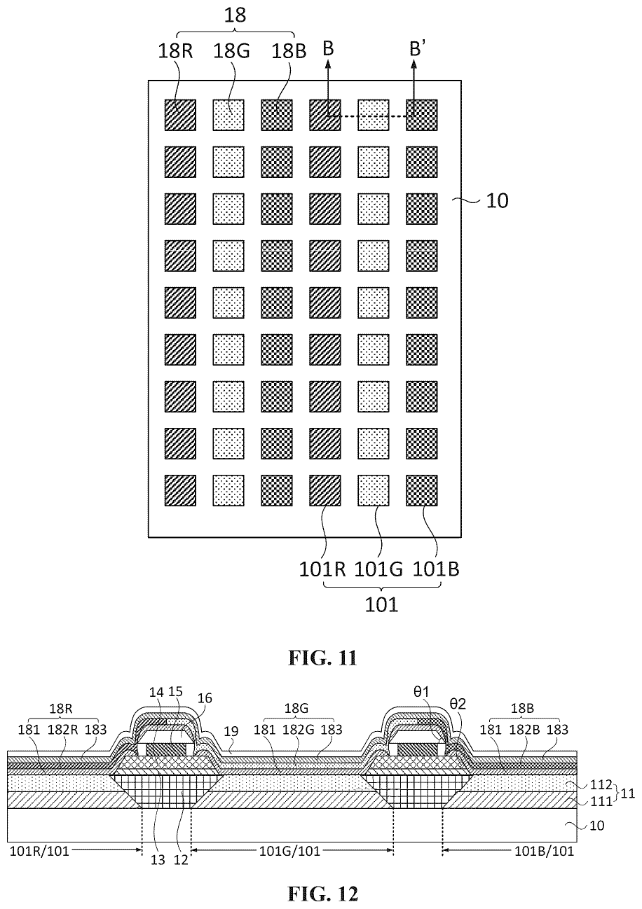

FIG. 11 is another structural diagram of the organic light-emitting display device according to an embodiment of the present disclosure, and FIG. 12 is a sectional view taken along B-B′ of FIG. 11. As shown in FIGS. 11 and 12, in one or more embodiments, the organic light-emitting layers 18 disposed on the anodes 11 are further included in the pixel regions 101. The organic light-emitting layers 18 include organic light-emitting layers 18 that emit light in multiple colors. In the row or column direction, the organic light-emitting layers 18 in the adjacent pixel regions 101 emit light in different colors.

In one or more embodiments, as shown in FIGS. 11 and 12, the organic light-emitting layer 18 is disposed on the anode 11, and the cathode 19 is disposed on the organic light-emitting layer 18. When the electron and the hole are injected into the organic light-emitting layer 18 from the cathode 19 and the anode 11, respectively, the electron and the hole are recombined in the organic light-emitting layer 18, releasing energy to emit light.

The color of the light emitted from the organic light-emitting layer 18 may depend on the material of the organic light-emitting layer 18.

As shown in FIGS. 11 and 12, the pixel regions 101 may be divided into red pixel regions 101R, green pixel regions 101G, and blue pixel regions 101B. The organic light-emitting layer 18 may include red organic light-emitting layers 18R disposed in the red pixel regions 101R, green organic light-emitting layers 18G disposed in the green pixel regions 101G, and blue organic light-emitting layers 18B disposed in the blue pixel regions 101B to display a color image, which is not limited thereto. In some embodiments, the organic light-emitting layers 18 may also include white organic light-emitting layers or organic light-emitting layers in another color in addition to the organic light-emitting layers in the preceding three colors.

In this organic light-emitting display device, the red organic light-emitting layer 18R includes a red light-emitting material layer 182R, the green organic light-emitting layer 18G includes a green light-emitting material layer 182G, and the blue organic light-emitting layer 18B includes a blue light-emitting material layer 182B. In addition, the organic materials of the red light-emitting material layer 182R, the green light-emitting material layer 182G, and the blue light-emitting material layer 182B are typically different from each other.

In the related art, in the preparation process of the organic light-emitting display device with the preceding light-emitting structure, it is typically necessary to use a fine metal mask (FMM) to evaporate and form the red light-emitting material layer, the green light-emitting material layer, and the blue light-emitting material layer separately. Since the FMM has problems such as a manufacturing deviation, an alignment deviation, and thermal deformation, the position where the organic light-emitting material layer is formed may deviate significantly from a preset position. Moreover, the FMM is costly, which increases the manufacturing costs of the organic light-emitting display device. In addition, for a high-resolution microdisplay, it is difficult to achieve an ultra-small hollow metal opening with the FMM due to the difficulty of the process.

In this embodiment, organic light-emitting layers 18 in different colors may be formed in different pixel regions 101 through an etching process, respectively. In addition, at least part of common films in the organic light-emitting layer 18 are separated by the fifth insulating layer 16 and the fourth insulating layer 15. Thus, the at least part of the common films between the adjacent pixel regions 101 are isolated from each other, thereby reducing the leakage current between the adjacent pixel regions 101. The FMM is not required. Thus, problems such as the significant deviation between the position where the organic light-emitting material layer is formed and the preset position can be avoided, where the significant deviation is caused by the manufacturing deviation, alignment deviation, and thermal deformation of the FMM. This helps meet the requirement of a user for high resolution on the organic light-emitting display device. Additionally, the FMM is not used so that the manufacturing costs of the organic light-emitting display device can be reduced.

With continued reference to FIGS. 3 and 12, in one or more embodiments, a first included angle θ1 is between the bottom surface of the fifth insulating layer 16 and a side surface of the fifth insulating layer 16. The range of the first included angle θ1 is from 20° to 60°.

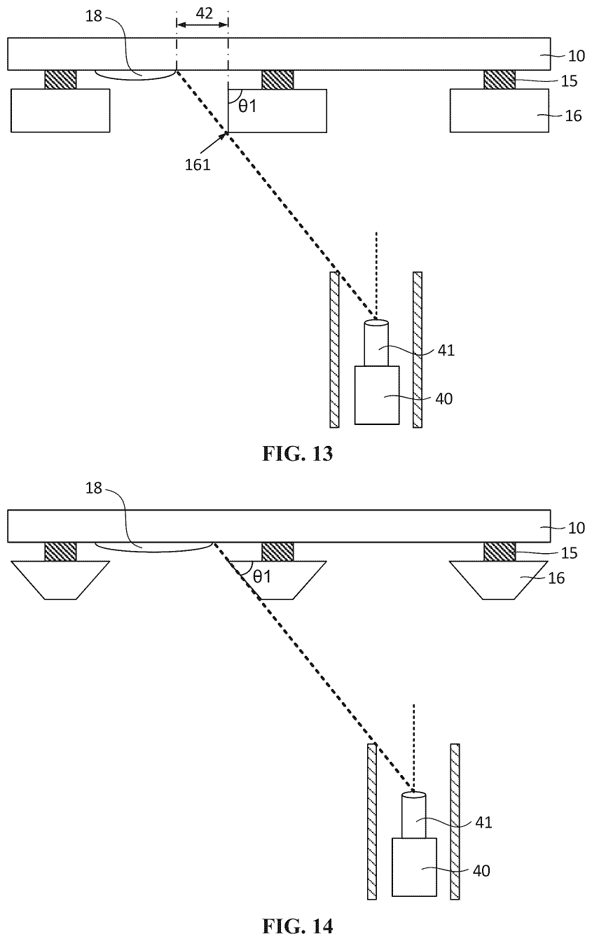

In one or more embodiments, FIG. 13 is a structural diagram showing an evaporation process in the related art. As shown in FIG. 13, in the evaporation process, a certain relative movement exists between an evaporation source 40 and the substrate 10. An evaporation material is heated and gasified in the evaporation source 40, then ejected through a nozzle 41, and evaporated onto the substrate 10 through an opening formed by fifth insulating layers 16 to form the corresponding organic light-emitting layer 18. In the evaporation and deposition process, the evaporation material is ejected from the nozzle 41 in a beam shape. The fifth insulating layer 16 blocks the evaporation material. When the first angle θ1 between the bottom surface of the fifth insulating layer 16 facing the substrate 10 and the side surface of the fifth insulating layer 16 is relatively large (for example, θ1 ≥90°), a vertex 161 of the fifth insulating layer 16 near the evaporation source 40 creates a relatively large hidden region 42 due to the thickness of the fifth insulating layer 16. As a result, the evaporation material cannot be uniformly deposited to form a film in the hidden region 42, leading to poor evaporation.

With continued reference to FIGS. 3 and 12, in this embodiment, the first included angle θ1 between the bottom surface of the fifth insulating layer 16 and the side surface of the fifth insulating layer 16 is set to be less than or equal to 60°. The top surface of the fifth insulating layer 16 refers to the side surface of the fifth insulating layer 16 facing away from the substrate 10, and the bottom surface of the fifth insulating layer 16 refers to the side surface of the fifth insulating layer 16 facing the substrate 10.

As shown in FIGS. 3 and 12, in this case, the width of the top surface of the fifth insulating layer 16 is less than the width of the bottom surface of the fifth insulating layer 16. That is, the length of the bottom surface of the fifth insulating layer 16 in the lateral direction is greater than the length of the top surface of the fifth insulating layer 16 in the lateral direction. In other words, the projection area of the bottom surface of the fifth insulating layer 16 on the substrate 10 is larger than the projection area of the top surface of the fifth insulating layer 16 on the substrate 10.

FIG. 14 is a structural diagram showing another evaporation process according to an embodiment of the present disclosure. As shown in FIG. 14, when the first included angle θ1 between the bottom surface of the fifth insulating layer 16 and the side surface of the fifth insulating layer 16 is less than or equal to 60°, the amount of evaporation materials blocked by the fifth insulating layer 16 can be reduced. Thus, more evaporation materials are enabled to pass through the opening formed by the fifth insulating layers 16. Accordingly, the area of the organic light-emitting layer 18 formed by the evaporation material on the substrate 10 can be increased, thereby allowing the region covered by the organic light-emitting layer 18 to be closer to the pattern of a designed region and improving the evaporation precision of the organic light-emitting layer 18.

Furthermore, the width of the top surface of the fifth insulating layer 16 is a design value predetermined according to specific requirements. The smaller the first included angle θ1 between the bottom surface of the fifth insulating layer 16 and the side surface of the fifth insulating layer 16, the larger the width of the bottom surface of the fifth insulating layer 16 and the larger the overall width of the fifth insulating layer 16. Then, during the preparation of the organic light-emitting layer 18, the fifth insulating layer 16 blocks a relatively large area of the material of the organic light-emitting layer 18, thereby reducing the coverage area of the organic light-emitting layer 18 in the pixel region 101. This can reduce the area of the organic light-emitting layer 18 that can effectively emit light. That is, the portion in the pixel region 101 to actually emit light becomes smaller, which affects the overall brightness and energy efficiency of the display device.

In this embodiment, the first included angle θ1 between the bottom surface of the fifth insulating layer 16 and the side surface of the fifth insulating layer 16 is set to be greater than or equal to 20°. Thus, the first included angle θ1 can be prevented from being excessively small and causing the overall width of the fifth insulating layer 16 to be excessively large. Accordingly, it is ensured that the overall width of the fifth insulating layer 16 is relatively small. During the preparation of the organic light-emitting layer 18, the area of the material of the organic light-emitting layer 18 blocked by the fifth insulating layer 16 can be reduced, and the coverage area of the organic light-emitting layer 18 in the pixel region 101 is increased. Furthermore, the area of the organic light-emitting layer 18 that can effectively emit light is increased, which improves the overall brightness and energy efficiency of the display device.

In addition, the first included angle θ1 is greater than or equal to 20°, which can prevent the edge of the fifth insulating layer 16 from being excessively thin. Thus, the edge of the fifth insulating layer 16 is prevented from being damaged in the subsequent processes, which helps ensure the integrity of the fifth insulating layer 16.

With continued reference to FIGS. 3 and 12, in one or more embodiments, the thickness of the fifth insulating layer 16 is 10 nm to 100 nm.

The thickness of the fifth insulating layer 16 is set to be less than or equal to 100 nm, which helps reduce the amount of evaporation materials blocked by the fifth insulating layer 16. Thus, more evaporation materials are enabled to pass through the opening formed by the fifth insulating layers 16. Accordingly, the area of the organic light-emitting layer 18 formed by the evaporation material on the substrate 10 can be increased, thereby allowing the region covered by the organic light-emitting layer 18 to be closer to the pattern of the designed region and improving the evaporation precision of the organic light-emitting layer 18.

In addition, the thickness of the fifth insulating layer 16 is less than or equal to 100 nm so that the thickness of the organic light-emitting display device is not excessively increased, which helps implement a light and thin design of the organic light-emitting display device. Additionally, a relatively thin fifth insulating layer 16 means that fewer materials are used in a manufacturing process, which helps reduce costs.

Furthermore, the thickness of the fifth insulating layer 16 is set to be greater than or equal to 10 nm so that the structural strength of the fifth insulating layer 16 can be ensured. Thus, the risk is reduced that the edge of the fifth insulating layer 16 is damaged or deformed. This helps maintain the stability of the size and position of the hidden region formed by the fifth insulating layer 16. Accordingly, it is ensured that the organic light-emitting layer 18 can be precisely deposited at the preset position, thereby improving the precision and reliability of the manufacturing process.

With continued reference to FIGS. 3 and 12, in one or more embodiments, the thickness of the fourth insulating layer 15 is 10 nm to 100 nm.

The thickness of the fourth insulating layer 15 is set to be greater than or equal to 10 nm so that the bottom surface of the fifth insulating layer 16 and the top surface of the third insulating layer 14 can have a sufficient height difference. This helps partially separate the organic light-emitting layer 18 deposited on the upper surface of the fifth insulating layer 16 and the organic light-emitting layer 18 deposited on the upper surface of the third insulating layer 14, thereby preventing the crosstalk between adjacent pixels.

In addition, the thickness of the fourth insulating layer 15 is set to be less than or equal to 100 nm so that the distance between the fifth insulating layer 16 and the substrate 10 is not excessively increased. This helps reduce a shadow effect in the evaporation process and reduce the deviation between the pattern size of the actually evaporated organic light-emitting layer 18 and a design value, improving the precision of the evaporation process.

With continued reference to FIGS. 3 and 12, in one or more embodiments, the edge of the third insulating layer 14 is beyond the edge of the fourth insulating layer 15.

As shown in FIGS. 3 and 12, the length of the third insulating layer 14 in the lateral direction may be greater than the length of the fourth insulating layer 15 in the lateral direction. In other words, the projection area of the third insulating layer 14 on the substrate 10 is larger than the projection area of the fourth insulating layer 15 on the substrate 10.

With such a configuration, when the first carrier adjustment layer 181 is prepared, the first carrier adjustment layer 181 is raised at the edge of the third insulating layer 14. Thus, the transmission path length of the current on the first carrier adjustment layer 181 can be increased, which helps reduce the leakage current between the adjacent pixel regions 101.

With continued reference to FIGS. 3 and 12, in one or more embodiments, a second included angle θ2 is between the bottom surface of the third insulating layer 14 and a side surface of the third insulating layer 14. The range of the second included angle θ2 is from 20° to 60°.

In one or more embodiments, as shown in FIGS. 3 and 12, the top surface of the fifth insulating layer 16 refers to the side surface of the fifth insulating layer 16 facing away from the substrate 10, and the bottom surface of the fifth insulating layer 16 refers to the side surface of the fifth insulating layer 16 facing the substrate 10.

In this embodiment, the second included angle θ2 between the bottom surface of the third insulating layer 14 and the side surface of the third insulating layer 14 is set to be less than or equal to 60°. In this case, a relatively smooth transition region is formed on the side surface of the third insulating layer 14 so that it is easier for the organic light-emitting layer 18 to adhere to the side surface of the third insulating layer 14 during deposition. This helps reduce defects of the organic light-emitting layer 18 on the side surface of the third insulating layer 14, improves the uniformity of the organic light-emitting layer 18, and ensures that the thickness and performance of the organic light-emitting layer 18 are consistent in the entire pixel region 101.

Furthermore, the width of the top surface of the third insulating layer 14 is a design value predetermined according to the specific requirements. The smaller the second included angle θ2 between the bottom surface of the third insulating layer 14 and the side surface of the third insulating layer 14, the larger the width of the bottom surface of the third insulating layer 14 and the larger the overall width of the third insulating layer 14. As a result, the portion in the pixel region 101 to actually emit light becomes smaller, which affects the overall brightness and energy efficiency of the display device.

In this embodiment, the second included angle θ2 between the bottom surface of the third insulating layer 14 and the side surface of the third insulating layer 14 is set to be greater than or equal to 20°. Thus, the second included angle θ2 can be prevented from being excessively small and causing the overall width of the third insulating layer 14 to be excessively large. Accordingly, it is ensured that the overall width of the third insulating layer 14 is relatively small, and the area of the pixel region 101 that can effectively emit light is increased, which improves the overall brightness and energy efficiency of the display device.

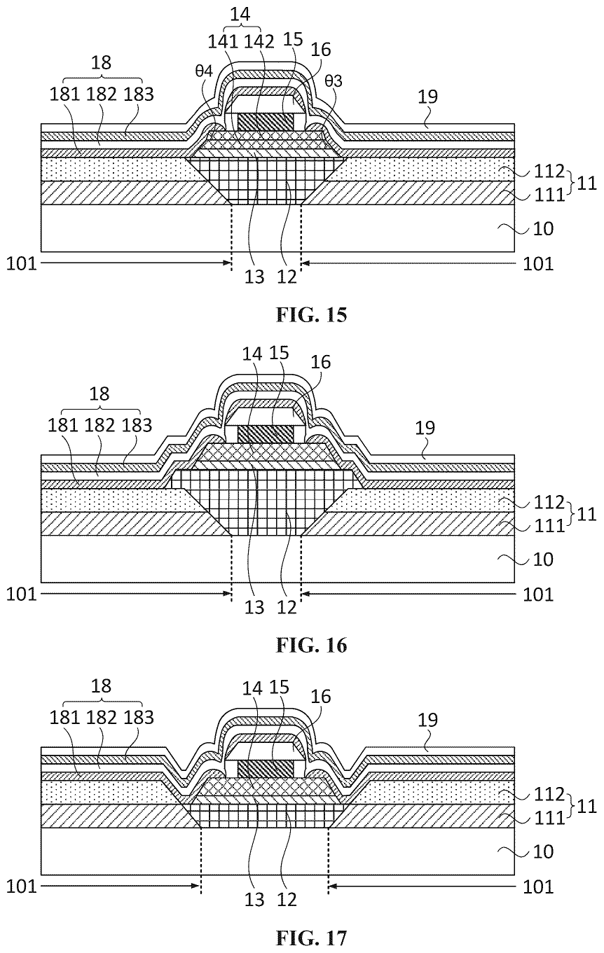

FIG. 15 is another sectional view showing a partial structure of the organic light-emitting display device according to an embodiment of the present disclosure. As shown in FIG. 15, in one or more embodiments, the third insulating layer 14 includes a first insulating section 141 located on the second insulating layer 13 and a second insulating section 142 located on the first insulating section 141. A third included angle θ3 is between a side surface of the first insulating section 141 and the bottom surface of the third insulating layer 14. A fourth included angle θ4 is between a side surface of the second insulating section 142 and the bottom surface of the third insulating layer 14. The fourth included angle θ4 is greater than the third included angle θ3.

In one or more embodiments, as shown in FIG. 15, the third insulating layer 14 includes two stacked films. The two stacked films are the first insulating section 141 and the second insulating section 142, respectively. The first insulating section 141 is located between the second insulating layer 13 and the second insulating section 142.

The top surface of the first insulating section 141 refers to the side surface of the first insulating section 141 facing away from the substrate 10, and the bottom surface of the first insulating section 141 refers to the side surface of the first insulating section 141 facing the substrate 10. The top surface of the second insulating section 142 refers to the side surface of the second insulating section 142 facing away from the substrate 10, and the bottom surface of the second insulating section 142 refers to the side surface of the second insulating section 142 facing the substrate 10.

In this embodiment, the third included angle θ3 between the side surface of the first insulating section 141 and the bottom surface of the third insulating layer 14 is configured to be different from the fourth included angle θ4 between the side surface of the second insulating section 142 and the bottom surface of the third insulating layer 14.

The third included angle θ3 between the side surface of the first insulating section 141 and the bottom surface of the third insulating layer 14 is relatively small so that a relatively smooth transition region is formed on the side surface of the first insulating section 141. Thus, it is easier for the organic light-emitting layer 18 to adhere to the side surface of the first insulating section 141 during the deposition so that the organic light-emitting layer 18 is gently raised through the edge of the first insulating section 141.

In addition, the fourth included angle θ4 between the side surface of the second insulating section 142 and the bottom surface of the third insulating layer 14 is relatively large so that the extent to which the organic light-emitting layer 18 is raised can be gradually increased. Thus, the film quality of the organic light-emitting layer 18 can be ensured. In addition, the transmission path length of the current on the first carrier adjustment layer 181 in the organic light-emitting layer 18 is increased, thereby reducing the leakage current between the adjacent pixel regions 101.

Additionally, at the edge of the second insulating section 142, the relatively large fourth included angle θ4 can thin or even cut off part of the films in the organic light-emitting layer 18 in advance. Thus, the continuity of the organic light-emitting layer 18 in this region is reduced. This helps reduce the leakage current between the adjacent pixel regions 101 and improve the electrical isolation effect between the adjacent pixel regions.

It is to be noted that the first insulating section 141 and the second insulating section 142 may be two parts of the same film. In this case, only one deposition process is required to complete the preparation of the third insulating layer 14, which reduces process steps and manufacturing processes. Thus, the production efficiency can be improved, and a production cycle is shortened. In addition, the improvement of the material consistency and film uniformity of the first insulating section 141 and the second insulating section 142 is facilitated.

An etching parameter may be set such that the third included angle θ3 between the side surface of the first insulating section 141 and the bottom surface of the third insulating layer 14 is different from the fourth included angle θ4 between the side surface of the second insulating section 142 and the bottom surface of the third insulating layer 14. The embodiment of the present disclosure imposes no specific limitation in this respect.

In other embodiments, the first insulating section 141 and the second insulating section 142 may be different films. In this case, the materials and etching parameters of the first insulating section 141 and the second insulating section 142 can be independently controlled so that material selection and process parameter settings of the first insulating section 141 and the second insulating section 142 are more flexible. The embodiment of the present disclosure imposes no specific limitation in this respect.

With continued reference to FIG. 15, in one or more embodiments, the range of the third included angle θ3 is from 20° to 60°, and the range of the fourth included angle θ4 is from 60° to 90°.

As shown in FIG. 15, the third included angle θ3 between the side surface of the first insulating section 141 and the bottom surface of the third insulating layer 14 is set to be less than or equal to 60° so that a relatively smooth transition region is formed on the side surface of the first insulating section 141. Thus, it is easier for the organic light-emitting layer 18 to adhere to the side surface of the first insulating section 141 during the deposition. This helps reduce defects of the organic light-emitting layer 18 on the side surface of the first insulating section 141.

In addition, the width of the top surface of the third insulating layer 14 is the design value predetermined according to the specific requirements. The third included angle θ3 between the side surface of the first insulating section 141 and the bottom surface of the third insulating layer 14 is set to be greater than or equal to 20°. Thus, the third included angle θ3 can be prevented from being excessively small and causing the overall width of the first insulating section 141 to be excessively large. Accordingly, it is ensured that the overall width of the third insulating layer 14 is relatively small, and the area of the pixel region 101 that can effectively emit light is increased, which improves the overall brightness and energy efficiency of the display device.

Furthermore, the fourth included angle θ4 between the side surface of the second insulating section 142 and the bottom surface of the third insulating layer 14 is set to be greater than or equal to 60°, so as to enable the fourth included angle θ4 between the side surface of the second insulating section 142 and the bottom surface of the third insulating layer 14 to be greater than the third included angle θ3 between the side surface of the first insulating section 141 and the bottom surface of the third insulating layer 14. Thus, the extent to which the organic light-emitting layer 18 is raised is gradually increased. Accordingly, the film quality of the organic light-emitting layer 18 is ensured. In addition, the transmission path length of the current on the first carrier adjustment layer 181 in the organic light-emitting layer 18 is increased, thereby reducing the leakage current between the adjacent pixel regions 101.

Additionally, at the edge of the second insulating section 142, the relatively large fourth included angle θ4 can thin or even cut off the part of the films in the organic light-emitting layer 18 in advance. Thus, the continuity of the organic light-emitting layer 18 in this region is reduced. This helps reduce the leakage current between the adjacent pixel regions 101 and improve the electrical isolation effect between the adjacent pixel regions.

Furthermore, the fourth included angle θ4 between the side surface of the second insulating section 142 and the bottom surface of the third insulating layer 14 is set to be less than or equal to 90°. Thus, it is easier for the organic light-emitting layer 18 to adhere to the side surface of the second insulating section 142 during the deposition. This helps reduce defects of the organic light-emitting layer 18 on the side surface of the second insulating section 142. Additionally, the difficulty of the preparation process of the second insulating section 142 can be reduced so that it is easy to implement the preparation process of the second insulating section 142.

With continued reference to FIG. 15, in one or more embodiments, the thickness of the second insulating section 142 is greater than or equal to 10 nm.

The thickness of the second insulating section 142 is set to be greater than or equal to 10 nm. Thus, the extent to which the organic light-emitting layer 18 is raised can be effectively increased. Accordingly, this helps increase the transmission path length of the current on the first carrier adjustment layer 181 in the organic light-emitting layer 18, thereby reducing the leakage current between the adjacent pixel regions 101.

With continued reference to FIG. 3, in one or more embodiments, the top surface of the first insulating layer 12 is flush with the top surface of each of at least one anode 11; or, the top surface of the first insulating layer 12 is higher than the top surface of the anode 11; or, the top surface of the first insulating layer 12 is lower than the top surface of the anode 11.

The top surface of the first insulating layer 12 refers to the side surface of the first insulating layer 12 facing away from the substrate 10, and the top surface of the anode 11 refers to the side surface of the anode 11 facing away from the substrate 10.

As shown in FIG. 3, the top surface of the first insulating layer 12 is configured to be flush with the top surface of each of the at least one anode 11. That is, the top surface of the first insulating layer 12 and the top surface of each of the at least one anode 11 are at the same horizontal plane. In this case, the height of the top surface of the first insulating layer 12 is the same as the height of the top surface of the anode 11. Thus, a depression formed between two different anodes 11 can be filled by the first insulating layer 12 so that the subsequent film can be prepared on a relatively flat surface, thereby ensuring the continuity of the subsequent film.

FIG. 16 is another sectional view showing a partial structure of the organic light-emitting display device according to an embodiment of the present disclosure. As shown in FIG. 16, in one or more embodiments, the top surface of the first insulating layer 12 is higher than the top surface of the anode 11. That is, the height difference between the top surface of the first insulating layer 12 and the top surface of the anode 11 is a positive value. With such a configuration, when the first carrier adjustment layer 181 is prepared, the first carrier adjustment layer 181 is sequentially raised by the first insulating layer 12, the second insulating layer 13, and the third insulating layer 14, thereby increasing the spacing between the cathode 19 and the anode 11. Thus, the formation of relatively high brightness at the edge of the pixel is avoided. In addition, the transmission path length of the current on the first carrier adjustment layer 181 is increased, thereby helping reduce the leakage current between the adjacent pixel regions 101.

FIG. 17 is another sectional view showing a partial structure of the organic light-emitting display device according to an embodiment of the present disclosure. As shown in FIG. 17, in one or more embodiments, when the spacing between the adjacent anodes 11 is relatively large, the top surface of the first insulating layer 12 may be configured to be lower than the top surface of the anode 11. That is, the height difference between the top surface of the first insulating layer 12 and the top surface of the anode 11 is a negative value. Thus, the amount of used materials can be reduced, thereby helping reduce the manufacturing costs.

With continued reference to FIGS. 3, 16, and 17, in one or more embodiments, the anode 11 includes a reflective anode layer 111 and a transparent anode layer 112 that are stacked. The transparent anode layer 112 is located on the reflective anode layer 111. The top surface of the first insulating layer 12 is flush with the top surface of the reflective anode layer 111. Alternatively, the top surface of the first insulating layer 12 is higher than the top surface of the reflective anode layer 111.

In one or more embodiments, as shown in FIGS. 3, 16, and 17, the reflective anode layer 111 is disposed in the pixel region 101. The reflective anode layer 111 may be made of a metal material (such as silver or copper) with high electrical conductivity. Thus, the resistance of the anode 11 can be reduced, and the transmission efficiency of the current is improved.

Furthermore, a reflective electrode 14 in each pixel region 101 may have the same thickness so that the manufacturing process can be simplified and the production efficiency is improved.

With continued reference to FIGS. 3, 16, and 17, the transparent anode layer 112 is also disposed on the reflective anode layer 111 in the pixel region 101. The transparent anode layer 112 is configured to form a microcavity effect. Transparent anode layers 112 of different thicknesses are disposed in pixel regions 101 displaying different colors so that the length of a microcavity is adjustable to enhance light in a displayed color. Thus, the luminescence efficiency of the light in the corresponding color is improved, thereby helping improve color purity.

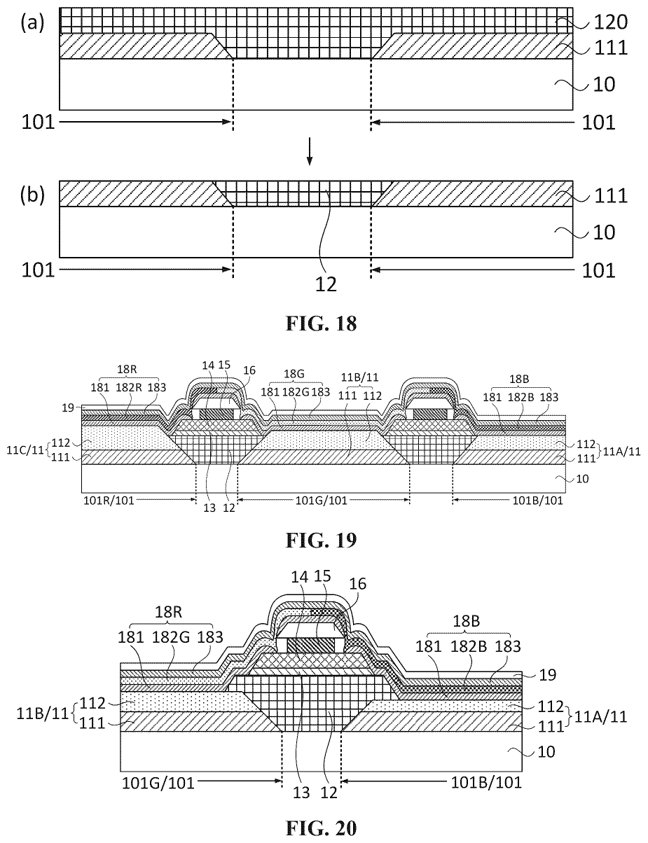

FIG. 18 provides schematic diagrams showing a flow of the manufacturing method of the organic light-emitting display device according to an embodiment of the present disclosure. As shown in FIGS. 17 and 18, in one or more embodiments, the top surface of the first insulating layer 12 is flush with the top surface of the reflective anode layer 111. That is, the top surface of the first insulating layer 12 and the top surface of the reflective anode layer 111 are at the same horizontal plane. In this case, the height of the top surface of the first insulating layer 12 is the same as the height of the top surface of the reflective anode layer 111. The top surface of the first insulating layer 12 refers to the side surface of the first insulating layer 12 facing away from the substrate 10, and the top surface of the reflective anode layer 111 refers to the side surface of the reflective anode layer 111 facing away from the substrate 10.

With such a configuration, when the organic light-emitting display device is prepared, as shown in FIG. 18(a), an entire first insulating material layer 120 may be deposited on the reflective anode layer 111. As shown in FIG. 18(b), the first insulating material layer 120 may be etched through a chemical mechanical polishing (CMP) process. The first insulating material layer 120 on the reflective anode layer 111 is polished away and the first insulating material layer 120 between two adjacent reflective anode layers 111 is retained so that the first insulating layer 12 is formed. The top surface of the first insulating layer 12 is flush with the top surface of the reflective anode layer 111. In addition, the top surface of the first insulating layer 12 and the top surface of the reflective anode layer 111 can form a flat and smooth surface. Thus, the subsequent film can be prepared on a relatively flat surface so that the formation quality of the subsequent film can be ensured.

It is to be noted that the main working principle of the CMP process is that under pressure and due to the existence of slurry, the polished film moves relative to a polishing pad. The CMP process relies on the highly organic combination of the mechanical grinding action of nano abrasives and the chemical action of various chemical reagents to reduce the thickness of the polished film. In addition, the surface of the polished film is allowed to meet the requirements of high flatness, low surface roughness, and low defectivity. It is unnecessary to use an additional mask when the first insulating layer 12 is formed with this process. Thus, the manufacturing costs can be reduced, the process is simplified, and the production efficiency is improved.

With continued reference to FIGS. 3 and 16, in one or more embodiments, the top surface of the first insulating layer 12 is higher than the top surface of the reflective anode layer 111. That is, the height difference between the top surface of the first insulating layer 12 and the top surface of the reflective anode layer 111 is a positive value. Such a configuration helps reduce the height difference between the region where the anode 11 is located and the region between the adjacent anodes 11. Thus, the subsequent film can be prepared on a relatively flat surface so that the formation quality of the subsequent film can be improved.

FIG. 19 is another sectional view showing a partial structure of the organic light-emitting display device according to an embodiment of the present disclosure. As shown in FIG. 19, in one or more embodiments, the anode 11 includes the reflective anode layer 111 and the transparent anode layer 112 that are stacked. The transparent anode layer 112 is located on the reflective anode layer 111. The anodes 11 include a first anode 11A, a second anode 11B, and a third anode 11C. The organic light-emitting layers 18 in the pixel regions 101 where the first anode 11A, the second anode 11B, and the third anode 11C are located emit light in different colors. The thickness of the transparent anode layer 112 in the first anode 11A is less than the thickness of the transparent anode layer 112 in the second anode 11B, and the thickness of the transparent anode layer 112 in the second anode 11B is less than the thickness of the transparent anode layer 112 in the third anode 11C. The top surface of the first insulating layer 12 is flush with the top surface of the first anode 11A.

For the manner in which the reflective anode layer 111 and the transparent anode layer 112 are disposed, reference may be made to any of the preceding embodiments. The details are not repeated here.

In this embodiment, the anodes 11 include the first anode 11A, the second anode 11B, and the third anode 11C that are located in the different pixel regions 101.

As shown in FIG. 19, in one or more embodiments, the pixel regions 101 may include a red pixel region 101R, a green pixel region 101G, and a blue pixel region 101B. It is to be understood that the red pixel region 101R emits light in red, the green pixel region 101G emits light in green, and the blue pixel region 101B emits light in blue. Then, the first anode 11A, the second anode 11B, and the third anode 11C may be the anode 11 in the blue pixel region 101B, the anode 11 in the green pixel region 101G, and the anode 11 in the red pixel region 101R, respectively.

The longer the cavity length of the microcavity formed by the transparent anode layer 112, the longer the wavelength of enhanced and outputted light.

In this embodiment, as shown in FIG. 19, description is performed by using an example in which the first anode 11A is located in the blue pixel region 101B, the second anode 11B is located in the green pixel region 101G, and the third anode 11C is located in the red pixel region 101R. The transparent anode layer 112 in the first anode 11A may be configured to be slightly thick so that the microcavity has a relatively short cavity length to enhance the output efficiency of the blue light, thereby improving the display color purity of the blue light. The transparent anode layer 112 in the second anode 11B is moderately thick so that the microcavity can have a moderate cavity length to enhance the output efficiency of the green light, thereby improving the display color purity of the green light. The transparent anode layer 112 in the third anode 11C is greatly thick so that the microcavity can have a relatively long cavity length to enhance the output efficiency of the red light, thereby improving the display color purity of the red light.

Furthermore, as shown in FIG. 19, the top surface of the first insulating layer 12 is flush with the top surface of the first anode 11A. That is, the top surface of the first insulating layer 12 is flush with the top surface of the anode 11 having the minimum top surface height. On the one hand, the height difference between the region where the anode 11 is located and the region between the adjacent anodes 11 is reduced so that the subsequent film can be prepared on a relatively flat surface. Thus, the formation quality of the subsequent film can be improved. On the other hand, in the process where the first insulating material layer is etched to form the first insulating layer 12, the anodes 11 in all the pixel regions 101 can be exposed through a single etching process by the first insulating layer 12. No additional etching step needs to be performed on the first insulating material layer through a masking process. Thus, the manufacturing process can be simplified, and the production efficiency is improved.

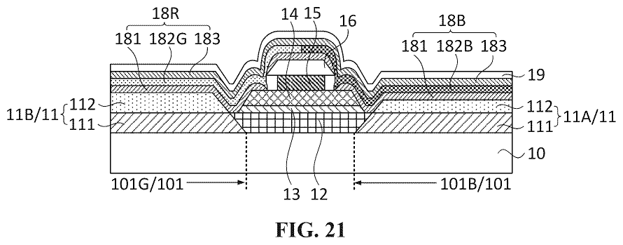

FIG. 20 is another sectional view showing a partial structure of the organic light-emitting display device according to an embodiment of the present disclosure, and FIG. 21 is another sectional view showing a partial structure of the organic light-emitting display device according to an embodiment of the present disclosure. As shown in FIGS. 20 and 21, in one or more embodiments, in the case where the top surface of the first insulating layer 12 is higher than the top surface of the anode 11 (as shown in FIG. 20) or in the case where the top surface of the first insulating layer 12 is lower than the top surface of the anode 11 (as shown in FIG. 21), the transparent anode layers 112 of different thicknesses may be disposed in the pixel regions 101 displaying the different colors. Thus, the length of the microcavity is adjusted so that the light in the displayed color is enhanced, thereby improving the color purity. The embodiment of the present disclosure imposes no specific limitation in this respect.

With continued reference to FIG. 3, in one or more embodiments, the distance L0 from an edge of the top surface of the third insulating layer 14 to an edge of the top surface of the anode 11 is greater than or equal to 0.

The top surface of the third insulating layer 14 refers to the side surface of the third insulating layer 14 facing away from the substrate 10, and the top surface of the anode 11 refers to the side surface of the anode 11 facing away from the substrate 10.

As shown in FIG. 3, on the side of the edge of the fifth insulating layer 16 facing the anode 11, the first carrier adjustment layer 181 is not cut off by the fifth insulating layer 16. Therefore, the leakage current transmitted on the first carrier adjustment layer 181 flows to the cathode 19 through the light-emitting material layer 182 on the third insulating layer 14, causing stray light to form at the corners and edges of the pixel.

In this embodiment, as shown in FIG. 3, in the direction parallel to the plane where the substrate 10 is located, the distance L0 from the edge of the top surface of the third insulating layer 14 to the edge of the top surface of the anode 11 is set to be greater than or equal to 0. Thus, the stray light formed by the organic light-emitting layer 18 on the third insulating layer 14 can be located in the gap region between the two adjacent anodes 11. The gap region is more distant from the reflective anode layer 111 so that the reflection of the stray light can be reduced, which helps reduce the output intensity of the stray light. Thus, the impact of the stray light on the display effect is reduced.

In addition, the distance L0 from the edge of the top surface of the third insulating layer 14 to the edge of the top surface of the anode 11 is set to be greater than or equal to 0, which can also reduce the impact of the third insulating layer 14 on the length of the microcavity. Thus, the improvement of the display color purity is facilitated.

In one or more embodiments, the organic light-emitting display device is a silicon-based micro organic light-emitting display device.

The silicon-based micro organic light-emitting display device combines a complementary metal oxide semiconductor (CMOS) silicon-based integrated circuit process and an OLED technology to directly integrate an OLED pixel array onto a silicon wafer so that a microdisplay is formed.

The silicon-based micro organic light-emitting display device has the characteristics of compactness, thinness, low power consumption, high brightness, a fast response speed, and a wide viewing angle. The silicon-based micro organic light-emitting display device is applicable in near-eye display devices, such as a virtual reality (VR) headset, an augmented reality (AR) headset, a heads-up display (HUD) system, and a mini projector, and other portable electronic products with strict requirements on a volume, a weight, and energy consumption.

In the embodiment of the present disclosure, the substrate 10 may be a silicon-based drive plane. The corresponding organic light-emitting layers 18 may be formed in the pixel regions 101 on the substrate 10 through an etching process (for example, a photolithography process including an exposure step and a development step). The process error thereof may be controlled to be about ±2 μm. The organic light-emitting layers 18 can have smaller pixel dimensions, higher resolution, and lower manufacturing costs than organic light-emitting layers 18 formed with the traditional FMM.

On the basis of the same inventive concept, an embodiment of the present disclosure further provides a manufacturing method of an organic light-emitting display device for preparing any organic light-emitting display device provided in the preceding embodiments. Structures and explanations of terms which are the same as or correspond to the structures and explanations of terms of the preceding embodiments are not repeated here.

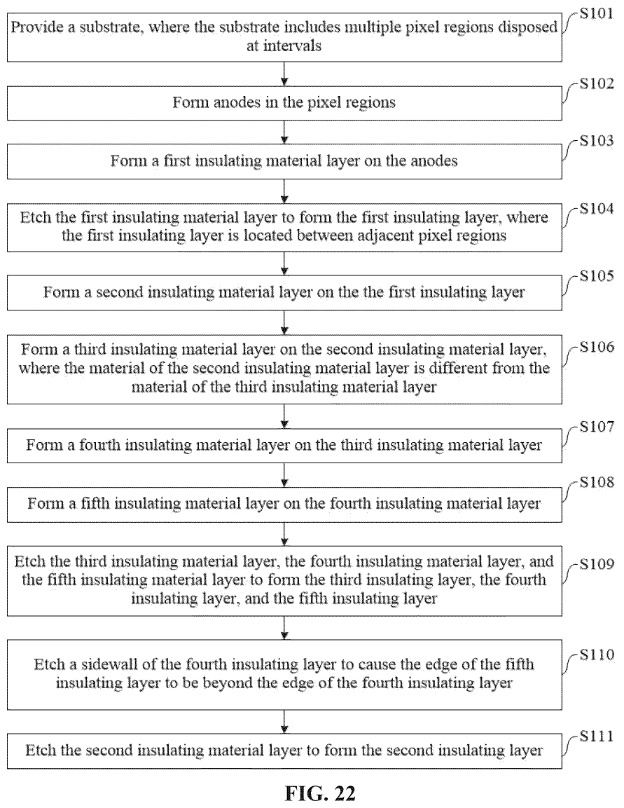

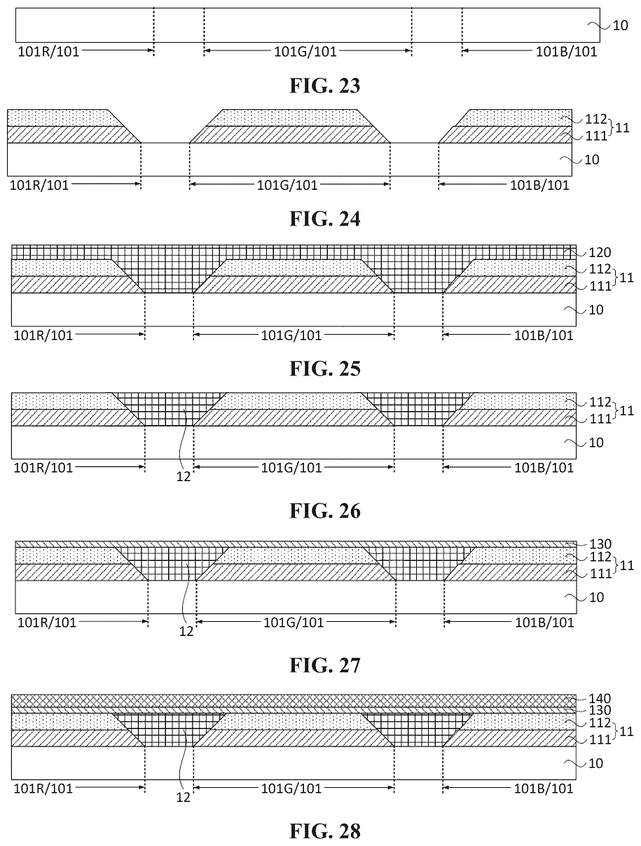

FIG. 22 is a flowchart of the manufacturing method of the organic light-emitting display device according to the embodiment of the present disclosure. FIGS. 23 to 33 are schematic diagrams showing a flow of the manufacturing method of the organic light-emitting display device according to an embodiment of the present disclosure. As shown in FIGS. 22 to 33, the manufacturing method includes the steps described below.

In S101, a substrate is provided, where the substrate includes multiple pixel regions disposed at intervals.

In one or more embodiments, as shown in FIG. 23, the substrate 10 may be a driving substrate, and the multiple pixel regions 101 arranged in an array are defined on the substrate 10. In the row or column direction, the pixels in adjacent pixel regions emit light in different colors.

For example, as shown in FIG. 23, in the row direction, the pixel regions 101 may be divided into a red pixel region 101R, a green pixel region 101G, and a blue pixel region 101B, but are not limited thereto. In some embodiments, the pixel regions 101 may also include an additional white pixel region or a pixel region in another color.

With continued reference to FIG. 4, in one or more embodiments, the substrate 10 includes a base 31. A drive transistor T corresponding to a pixel region 101 is disposed on the base 31. The drive transistor T is connected to a respective anode 11. The drive transistor T may supply, through the anode 11, an operating signal corresponding to brightness to a pixel, so as to drive the pixel to emit light.

The drive transistor T may include an active region T1, a gate T2, and a source and drain layer T3 that are stacked. The active region T1 may be formed in the base 31. The position of the active region T1 is not limited thereto.

In S102, anodes are formed in the multiple pixel regions.

In one or more embodiments, as shown in FIG. 24, the anodes 11 are formed in the pixel regions 101 on the substrate 10. The anodes 11 corresponding to the pixel regions 101 are configured through electrical isolation. The anode 11, as an electrode of the pixel, may be driven by a positive voltage from an external power supply to inject carriers (such as holes) into the pixel.

In one or more embodiments, as shown in FIG. 24, the anode 11 includes a reflective anode layer 111 and a transparent anode layer 112 that are stacked. The transparent anode layer 112 is located on the reflective anode layer 111. Transparent anode layers 112 of different thicknesses are disposed in pixel regions 101 displaying different colors so that the length of a microcavity is adjustable to enhance light in a displayed color. Thus, the luminescence efficiency of the light in the corresponding color is improved, thereby helping improve color purity, but the setting is not limited thereto.

In S103, a first insulating material layer is formed on the anodes.

In one or more embodiments, as shown in FIG. 25, the entire first insulating material layer 120 is deposited on the anodes 11.

The material of the first insulating material layer 120 may include at least one of silicon oxide (SiO) or silicon nitride (SiN). The silicon oxide and the silicon nitride have relatively high resistivity and can provide good insulation between the adjacent anodes 11. In addition, the silicon oxide and the silicon nitride also have very high chemical stability and excellent high-temperature stability and are less prone to corrosion from moisture, oxygen, and other harmful gases in the environment. The silicon oxide and the silicon nitride can maintain good insulating properties in a high-temperature environment, which helps prolong the service life of a device.

In S104, the first insulating material layer is etched so that the first insulating layer is formed, where the first insulating layer is located between adjacent pixel regions.

In one or more embodiments, as shown in FIG. 26, the first insulating material layer 120 may be etched through a photolithography process or a CMP process so that the first insulating material layer 120 on the reflective anode layer 111 is removed and the first insulating material layer 120 between two adjacent reflective anode layers 111 is retained. This operation aims to form a first insulating layer 12 between two adjacent pixel regions 101. The first insulating layer 12 helps ensure electrical insulation between two adjacent anodes 11. In addition, since the anode 11 has a certain thickness, a depression is formed between the two anodes 11. The first insulating layer 12 is filled between the two adjacent anodes 11, which also helps reduce the height difference between the region where the anodes 11 are located and the region where the depression is located. Thus, a subsequent film can be prepared on a relatively flat surface so that the continuity of the subsequent film can be ensured.

In S105, a second insulating material layer is formed on the first insulating layer.

In one or more embodiments, as shown in FIG. 27, the entire second insulating material layer 130 is deposited on the first insulating layer 12.

In S106, a third insulating material layer is formed on the second insulating material layer, where the material of the second insulating material layer is different from the material of the third insulating material layer.

In one or more embodiments, as shown in FIG. 28, the entire third insulating material layer 140 is deposited on the second insulating material layer 130.

In one or more embodiments, the material of the third insulating material layer 140 includes at least one of silicon nitride (SiN), silicon oxide (SiO), silicon oxynitride (SiON), or amorphous silicon (a-Si).

The silicon nitride (SiN), the silicon oxide (SiO), and the silicon oxynitride (SiON) have relatively high resistivity and can provide good insulation for the first carrier adjustment layer 181 located on the upper surface of the third insulating layer 14. In addition, the silicon nitride (SiN), the silicon oxide (SiO), and the silicon oxynitride (SiON) also have good chemical stability and thermal stability. The silicon nitride (SiN), the silicon oxide (SiO), and the silicon oxynitride (SiON) can maintain good insulating properties in a high-temperature environment, which helps prolong the service life of the device. The amorphous silicon (a-Si) may be deposited with various deposition methods, such as PECVD. The amorphous silicon (a-Si) has good process compatibility and good mechanical stability and can provide strong structural support, which helps ensure the stability of the structure in subsequent processes.

In S107, a fourth insulating material layer is formed on the third insulating material layer.

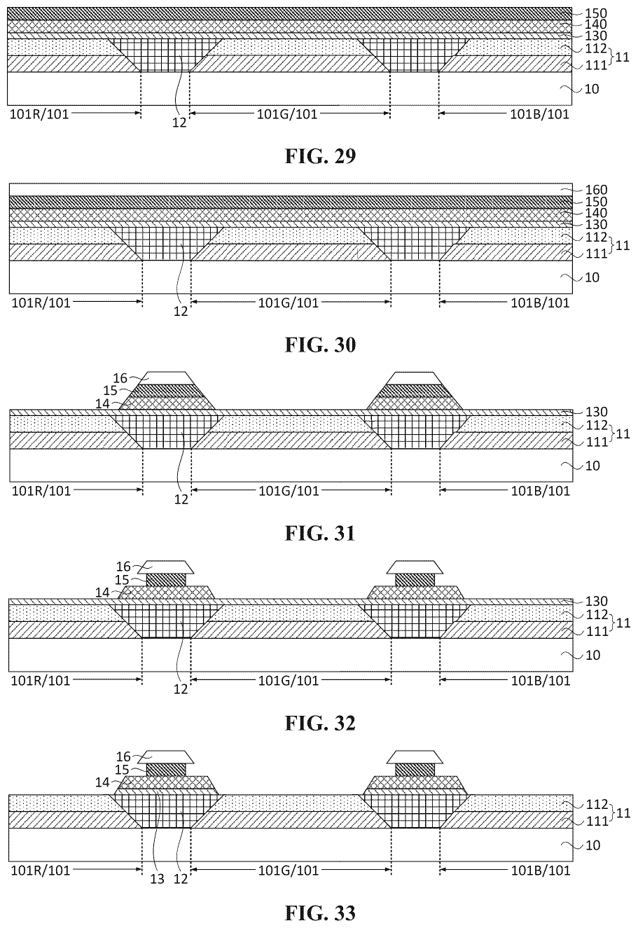

In one or more embodiments, as shown in FIG. 29, the entire fourth insulating material layer 150 is deposited on the third insulating material layer 140.

In one or more embodiments, the material of the fourth insulating material layer 150 includes at least one of silicon nitride (SiN), silicon oxide (SiO), silicon oxynitride (SiON), or amorphous silicon (a-Si), but is not limited thereto.

In S108, a fifth insulating material layer is formed on the fourth insulating material layer.

In one or more embodiments, as shown in FIG. 30, the entire fifth insulating material layer 160 is deposited on the fourth insulating material layer 150.

In one or more embodiments, the material of the fifth insulating material layer 160 includes at least one of silicon nitride (SiN), silicon oxide (SiO), silicon oxynitride (SiON), or amorphous silicon (a-Si), but is not limited thereto.

In S109, the third insulating material layer, the fourth insulating material layer, and the fifth insulating material layer are etched so that the third insulating layer, the fourth insulating layer, and the fifth insulating layer are formed.

In one or more embodiments, as shown in FIG. 31, the third insulating material layer 140, the fourth insulating material layer 150, and the fifth insulating material layer 160 may be etched through the photolithography process or a dry etching process to form the third insulating layer 14, the fourth insulating layer 15, and the fifth insulating layer 16 that are located between the adjacent pixel regions 101. The third insulating layer 14, the fourth insulating layer 15, and the fifth insulating layer 16 are disposed around the pixel region 101 and define regions that may be in any shape such as a rectangle, a polygon, or a circle. The shapes of the regions are not specifically limited in the embodiment of the present disclosure.

The third insulating material layer 140, the fourth insulating material layer 150, and the fifth insulating material layer 160 are etched in the same etching process to form the third insulating layer 14, the fourth insulating layer 15, and the fifth insulating layer 16. Thus, the process cycle can be shortened, and manufacturing costs are reduced.

Furthermore, the material of the second insulating material layer 130 is different from the material of the third insulating material layer 140. Then, in the preceding process where the third insulating material layer 140, the fourth insulating material layer 150, and the fifth insulating material layer 160 are etched, since the material of the second insulating material layer 130 is different, the second insulating material layer 130 can protect the first insulating layer 12 under the second insulating material layer 130 so that the first insulating layer 12 is prevented from being damaged by etching. Thus, the quality and flatness of the subsequent film (such as the organic light-emitting layer) deposited on the first insulating layer 12 are improved, thereby improving the luminescence efficiency and uniformity.

In S110, a sidewall of the fourth insulating layer is etched to cause the edge of the fifth insulating layer to be beyond the edge of the fourth insulating layer.

In one or more embodiments, as shown in FIG. 32, the sidewalls of the fourth insulating layer 15 are etched. A suitable etching gas or liquid may be selected for the fourth insulating layer 15 so that the etching speed of the fourth insulating layer 15 is much greater than the etching speed of the third insulating layer 14 and the etching speed of the fifth insulating layer 16. Thus, the sidewalls of the fourth insulating layer 15 are preferentially etched and recessed inward. Accordingly, the edge of the fifth insulating layer 16 is beyond the edge of the fourth insulating layer 15. In this case, the edge portion of the fifth insulating layer 16 forms an eaves structure on the edge of the fourth insulating layer 15.

In S111, the second insulating material layer 130 is etched so that second insulating layer 13 is formed.

In one or more embodiments, as shown in FIG. 33, the second insulating material layer 130 may be etched through the photolithography process or the dry etching process to form the second insulating layer 13 located between the adjacent pixel regions 101. The second insulating layer 13 is disposed around the pixel region 101 and defines a region that may be in any shape such as a rectangle, a polygon, or a circle. The shape of the region is not specifically limited in the embodiment of the present disclosure.

The embodiment of the present disclosure provides the manufacturing method of the organic light-emitting display device. The second insulating material layer is disposed between the first insulating layer and the third insulating layer, and the material of the second insulating material layer is different from the materials of the third insulating material layer, the fourth insulating material layer, and the fifth insulating material layer that are on the second insulating material layer. In the process where the third insulating material layer, the fourth insulating material layer, and the fifth insulating material layer are etched to form the third insulating layer, the fourth insulating layer, and the fifth insulating layer, the second insulating material layer is used for block etching so that the first insulating layer is protected from being damaged by etching. Thus, the quality and flatness of the subsequent film (such as the organic light-emitting layer) deposited on the first insulating layer are improved, thereby improving the luminescence efficiency and the uniformity.

In one or more embodiments, etching the second insulating material layer includes the operation described below.

The third insulating layer is used as a mask such that the second insulating material layer is etched.

In one or more embodiments, as shown in FIG. 10, in the process where the second insulating material layer 130 is etched to form the second insulating layer 13, the third insulating layer 14 can be directly used as the mask to etch the second insulating material layer 130, eliminating the need for an additional mask. Thus, the manufacturing costs can be reduced, the process is simplified, and production efficiency is improved. In addition, the third insulating layer 14 is used as the mask so that higher etching precision can be achieved and it is ensured that the edge of the second insulating layer 13 is aligned with the edge of the third insulating layer 14. Thus, problems such as interlayer misalignment caused by a process error introduced by an additional masking step are reduced.

In one or more embodiments, the material of the second insulating material layer is different from the material of the first insulating layer.

In one or more embodiments, as shown in FIG. 8(d), after the third insulating layer 14, the fourth insulating layer 15, and the fifth insulating layer 16 are formed, the second insulating material layer 130 is etched so that the second insulating material layer 130 on the anode 11 is removed, forming the second insulating layer 13. The material of the second insulating material layer 130 is different from the material of the first insulating layer 12. Then, in the preceding process where the second insulating material layer 130 is etched, an etchant with high selectivity to the material of the second insulating material layer 130 may be selected, thereby reducing the damage to the first insulating layer 12 in the process where the second insulating material layer 130 is etched.

In one or more embodiments, the thickness of the second insulating material layer is 5 nm to 50 nm.

As shown in FIG. 8, the thickness of the second insulating material layer 130 is greater than or equal to 5 nm. In this case, the second insulating material layer 130 is sufficiently thick. In the process where the third insulating material layer 140, the fourth insulating material layer 150, and the fifth insulating material layer 160 are etched, it can be ensured that the second insulating material layer 130 is not completely removed in the etching process and thus can provide sufficient protection for the first insulating layer 12.

Furthermore, the thickness of the second insulating material layer 130 is less than or equal to 50 nm. In this case, the second insulating material layer 130 is not excessively thick. Then, in the process where the second insulating material layer 130 is etched to form the second insulating layer 13, no etching difficulty or no increase in process complexity is caused due to an excessively thick second insulating material layer 130.

In one or more embodiments, the material of the second insulating material layer includes at least one of aluminum oxide (Al₂O₃), titanium oxide (TiO₂), zirconium oxide (ZrO₂), or hafnium oxide (HfO₂).

The material of the second insulating material layer 130 is different from the material of the third insulating layer 14 and the material of the first insulating layer 12 to achieve etching selectivity.

As shown in FIG. 8, in the process where the third insulating material layer 140, the fourth insulating material layer 150, and the fifth insulating material layer 160 are etched, an etchant with high selectivity to the materials of the third insulating material layer 140, the fourth insulating material layer 150, and the fifth insulating material layer 160 may be selected. Then, in the etching process, the second insulating material layer 130 can protect the first insulating layer 12 under the second insulating material layer 130 so that the damage to the first insulating layer 12 is reduced. Thus, the structural integrity of the first insulating layer 12 is protected.

In addition, the aluminum oxide (Al₂O₃), the titanium oxide (TiO₂), the zirconium oxide (ZrO₂), and the hafnium oxide (HfO₂) have good chemical stability and mechanical strength, which help resist corrosion from an external environment and prolong the service life of the device.

It is to be understood that various forms of processes shown above may be adopted with steps reordered, added, or deleted. For example, the steps described in the present disclosure may be performed in parallel, sequentially, or in different sequences, as long as the desired results of the technical solutions of the present disclosure can be achieved, and no limitation is imposed herein.

The preceding embodiments do not limit the scope of the present disclosure. it Is to Be understood by those skilled in the art that various modifications, combinations, sub-combinations, and substitutions may be performed according to design requirements and other factors. Any modification, equivalent substitution, improvement, or the like that is made within the spirit and principle of the present disclosure is within the scope of the present disclosure.

What is claimed is:

1. An organic light-emitting display device, comprising:
a substrate comprising a plurality of pixel regions disposed at intervals;
anodes disposed in the plurality of pixel regions;
a first insulating layer filled between pixel regions among the plurality of pixel regions;
a second insulating layer disposed on the first insulating layer;
a third insulating layer disposed on the second insulating layer, wherein a material of the second insulating layer is different from a material of the third insulating layer;
a fourth insulating layer disposed on the third insulating layer; and
a fifth insulating layer disposed on the fourth insulating layer, wherein an edge of the fifth insulating layer is beyond an edge of the fourth insulating layer.

2. The organic light-emitting display device according to claim 1, wherein
the material of the second insulating layer is different from a material of the first insulating layer.

3. The organic light-emitting display device according to claim 1, wherein
a thickness of the second insulating layer is 5 nm to 50 nm.

4. The organic light-emitting display device according to claim 1, wherein
the material of the second insulating layer comprises at least one of aluminum oxide, titanium oxide, zirconium oxide, or hafnium oxide.

5. The organic light-emitting display device according to claim 1, wherein
a vertical projection of the second insulating layer on the substrate covers a vertical projection of the third insulating layer on the substrate;
wherein
the vertical projection of the second insulating layer on the substrate coincides with the vertical projection of the third insulating layer on the substrate.

6. The organic light-emitting display device according to claim 1, wherein
organic light-emitting layers disposed on the anodes are further comprised in the plurality of pixel regions, the organic light-emitting layers comprise organic light-emitting layers emitting light in a plurality of colors, and in a row or column direction, organic light-emitting layers in adjacent pixel regions among the plurality of pixel regions emit light in different colors.

7. The organic light-emitting display device according to claim 1, wherein
a first included angle is between a bottom surface of the fifth insulating layer and a side surface of the fifth insulating layer, and a range of the first included angle is from 20° to 60°.

8. The organic light-emitting display device according to claim 1, wherein
a thickness of the fifth insulating layer is 10 nm to 100 nm.

9. The organic light-emitting display device according to claim 1, wherein
a thickness of the fourth insulating layer is 10 nm to 100 nm.

10. The organic light-emitting display device according to claim 1, wherein
an edge of the third insulating layer is beyond the edge of the fourth insulating layer.

11. The organic light-emitting display device according to claim 1, wherein
a second included angle is between a bottom surface of the third insulating layer and a side surface of the third insulating layer, and a range of the second included angle is from 20° to 60°.

12. The organic light-emitting display device according to claim 1, wherein
the third insulating layer comprises a first insulating section located on the second insulating layer and a second insulating section located on the first insulating section;
a third included angle is between a side surface of the first insulating section and a bottom surface of the third insulating layer; and
a fourth included angle is between a side surface of the second insulating section and the bottom surface of the third insulating layer;
wherein the fourth included angle is greater than the third included angle.

13. The organic light-emitting display device according to claim 12, wherein
a range of the third included angle is from 20° to 60°; and
a range of the fourth included angle is from 60° to 90°.

14. The organic light-emitting display device according to claim 12, wherein
a thickness of the second insulating section is greater than or equal to 10 nm.

15. The organic light-emitting display device according to claim 1, wherein at least one of the following is satisfied:
a material of the fifth insulating layer comprises at least one of silicon nitride, silicon oxide, silicon oxynitride, or amorphous silicon;
a material of the fourth insulating layer comprises at least one of silicon nitride, silicon oxide, silicon oxynitride, or amorphous silicon;
or
a material of the third insulating layer comprises at least one of silicon nitride, silicon oxide, silicon oxynitride, or amorphous silicon.

16. The organic light-emitting display device according to claim 1, wherein
a distance from an edge of a top surface of the third insulating layer to an edge of a top surface of a respective one of the anodes is greater than or equal to 0.

17. The organic light-emitting display device according to claim 1, wherein
a top surface of the first insulating layer is flush with a top surface of at least one of the anodes;
or
a top surface of the first insulating layer is higher than a top surface of each of the anodes;
or
a top surface of the first insulating layer is lower than a top surface of each of the anodes.

18. The organic light-emitting display device according to claim 6, wherein
an anode of the anodes comprises a reflective anode layer and a transparent anode layer that are stacked, and the transparent anode layer is located on the reflective anode layer;
wherein a top surface of the first insulating layer is flush with a top surface of the reflective anode layer;
or
a top surface of the first insulating layer is higher than a top surface of the reflective anode layer.

19. The organic light-emitting display device according to claim 6, wherein
an anode of the anodes comprises a reflective anode layer and a transparent anode layer that are stacked, and the transparent anode layer is located on the reflective anode layer;
the anodes comprise a first anode, a second anode, and a third anode;
organic light-emitting layers in pixel regions where the first anode, the second anode, and the third anode are located emit light in different colors;
a thickness of a transparent anode layer in the first anode is less than a thickness of a transparent anode layer in the second anode, and the thickness of the transparent anode layer in the second anode is less than a thickness of a transparent anode layer in the third anode; and
a top surface of the first insulating layer is flush with a top surface of the first anode.

20. The organic light-emitting display device according to claim 1, wherein
the organic light-emitting display device is a silicon-based micro organic light-emitting display device.
